(19) United States
(12) Patent Application Publication
(10) Pub. No.: US 2026/0358573 A1
(43) Pub. Date: Nov. 12, 2026

(54) SEMICONDUCTOR PACKAGE INCLUDING OPTICAL BLOCK WITH MULTILAYER LENSES ALIGNED TO GRATING COUPLER

(71) Applicant: SAMSUNG ELECTRONICS CO., LTD., Suwon-si (KR)

(72) Inventor: Youngja KIM, Suwon-si (KR)

(73) Assignee: SAMSUNG ELECTRONICS CO., LTD., Suwon-si (KR)

(21) Appl. No.: 19/649,324

(22) Filed: Apr. 16, 2026

(30) Foreign Application Priority Data
May 9, 2025 (KR) 10-2025-0060576

(51) Int. Cl. G02B 6/42; H10W 90/28

(52) U.S. Cl. CPC G02B 6/4212; G02B 6/4206; G02B 6/4215; G02B 6/4239; G02B 6/4244; H10W 90/28

(57) ABSTRACT

A semiconductor package includes an electrical integrated circuit die and a photonic integrated circuit die having a light-guiding layer with a grating coupler. An optical block is mounted on the photonic integrated circuit die and aligned with the grating coupler to transmit optical signals between the optical block and the photonic integrated circuit die. A molding layer surrounds the electrical integrated circuit die and the optical block. The optical block has multilayer lenses with an intermediate lens layer positioned between the multilayer lenses. A top surface of the optical block is level with a top surface of the molding layer to improve optical alignment and reduce insertion loss.

### CROSS-REFERENCE TO RELATED APPLICATION

This application is based on and claims priority under 35 U.S.C. § 119 to Korean Patent Application No. 10-2025-0060576, filed on May 9, 2025, with the Korean Intellectual Property Office, the disclosure of which is incorporated herein by reference in its entirety.

### BACKGROUND

The inventive concept relates to a semiconductor package and, more specifically, to a semiconductor package including an electrical integrated circuit die and a photonic integrated circuit die.

High-resolution video streaming, virtual reality, Internet of Things (IoT), high-performance computing (HPC), artificial intelligence (AI), and machine learning (ML) are driving the demand for semiconductor packages capable of easily processing large volumes of data. Accordingly, semiconductor packages including electrical integrated circuit dies and photonic integrated circuit dies are being proposed as an alternative to conventional semiconductor packages.

### SUMMARY

The inventive concept provides a semiconductor package capable of easily integrating an electrical integrated circuit die and a photonic integrated circuit die and reducing insertion loss of light incident through an optical block.

According to an aspect of the inventive concept, there is provided a semiconductor package including an electrical integrated circuit die, a photonic integrated circuit die having a light-guiding layer including a grating coupler, an optical block mounted on the photonic integrated circuit die and aligned with the grating coupler, and a molding layer for molding the electrical integrated circuit die and the optical block, wherein the optical block includes multilayer lenses and an intermediate lens layer located between the multilayer lenses, and a top surface of the optical block does not protrude beyond a top surface of the molding layer and is coplanar with the top surface of the molding layer.

According to another aspect of the inventive concept, there is provided a semiconductor package including an electrical integrated circuit die, a photonic integrated circuit die having a light-guiding layer including a grating coupler, an optical block mounted on the photonic integrated circuit die and aligned with the grating coupler, and a molding layer for molding the electrical integrated circuit die and the optical block, wherein the optical block includes multilayer lenses, an intermediate lens layer located between the multilayer lenses, and lens bridges located on opposite sides of the intermediate lens layer and in contact with the molding layer, and a top surface of the optical block does not protrude beyond a top surface of the molding layer and is coplanar with the top surface of the molding layer.

According to another aspect of the inventive concept, there is provided a semiconductor package including a package substrate, an electrical integrated circuit die mounted on the package substrate, a photonic integrated circuit die spaced apart from the electrical integrated circuit die and mounted on the package substrate, the photonic integrated circuit die having a light-guiding layer including a grating coupler, an optical block mounted on the photonic integrated circuit die and aligned with the grating coupler, and a molding layer for molding the electrical integrated circuit die and the optical block, wherein the optical block includes multilayer lenses and an intermediate lens layer located between the multilayer lenses, and a top surface of the optical block does not protrude beyond a top surface of the molding layer and is coplanar with the top surface of the molding layer.

According to another aspect of the inventive concept, there is provided a method of manufacturing a semiconductor package, the method including preparing an electrical integrated circuit die, preparing an optical block including multilayer lenses and an intermediate lens layer located between the multilayer lenses, mounting at least one of the electrical integrated circuit die or the optical block on the photonic integrated circuit die, mounting the remaining one of the electrical integrated circuit die and the optical block, which has not been mounted, on the photonic integrated circuit die, forming a molding material layer for molding the electrical integrated circuit die and the optical block on the photonic integrated circuit die, and planarizing the molding material layer to form a molding layer such that a top surface of the optical block does not protrude beyond a top surface of the molding layer and is coplanar with the top surface of the molding layer.

### BRIEF DESCRIPTION OF THE DRAWINGS

Embodiments will be more clearly understood from the following detailed description taken in conjunction with the accompanying drawings in which:

FIG. 1A is a cross-sectional view showing a semiconductor package according to an embodiment;

FIG. 1B is an enlarged view of a portion A of FIG. 1A;

FIG. 2 is an enlarged view for describing an optical block of FIG. 1A;

FIG. 3 is a diagram for describing a path of light incident on the optical block of FIG. 1A;

FIG. 4 is a diagram for describing a path of light incident on a grating coupler of a photonic integrated circuit die through the optical block of FIG. 1A;

FIG. 5 is a cross-sectional view showing a semiconductor package according to an embodiment;

FIG. 6 is an enlarged view for describing an optical block of FIG. 5;

FIG. 7 is a cross-sectional view showing a semiconductor package according to an embodiment;

FIG. 8 is an enlarged view for describing an optical block of FIG. 7;

FIG. 9 is a cross-sectional view showing a semiconductor package according to an embodiment;

FIG. 10 is an enlarged view for describing the optical block of FIG. 9;

FIG. 11 is a cross-sectional view showing a semiconductor package according to an embodiment;

FIG. 12 is an enlarged view for describing an optical block of FIG. 11;

FIG. 13 is a cross-sectional view showing a semiconductor package according to an embodiment;

FIG. 14 is an enlarged view for describing an optical block of FIG. 13;

FIG. 15 is a cross-sectional view showing an optical block of a semiconductor package according to an embodiment;

FIG. 16 is a cross-sectional view showing an optical block of a semiconductor package according to an embodiment;

FIG. 17 is a cross-sectional view showing an optical block of a semiconductor package according to an embodiment;

FIG. 18 is a cross-sectional view showing an optical block of a semiconductor package according to an embodiment;

FIG. 19 is a cross-sectional view showing an optical block of a semiconductor package according to an embodiment;

FIGS. 20 to 24 are cross-sectional views for describing a method of manufacturing a semiconductor package, according to an embodiment;

FIG. 25 is a cross-sectional view for describing a semiconductor package according to an embodiment;

FIG. 26 is a cross-sectional view for describing a semiconductor package according to an embodiment;

FIG. 27 is a cross-sectional view for describing a semiconductor package according to an embodiment; and

FIG. 28 is a cross-sectional view for describing a semiconductor package according to an embodiment.

### DETAILED DESCRIPTION OF THE EMBODIMENTS

Hereinafter, embodiments of the inventive concept will be described in detail with reference to the accompanying drawings. The following embodiments of the inventive concept may be implemented by only any one thereof, and in addition, the following embodiments may be implemented by combining one or more thereof. Therefore, the inventive concept is not limited to a single embodiment.

In the present specification, a singular form of components may include a plural form unless they are clearly different from each other in context. In the specification, the drawings are exaggerated to more clearly describe the inventive concept.

In the present specification, while terms such as “first,” “second,” etc., may be used to describe various devices or components, such devices or components must not be limited to the above terms. The above terms are used only to distinguish one device or component from another device or component. Therefore, a “first” device or component mentioned hereinafter may be a “second” device or component within the inventive concept.

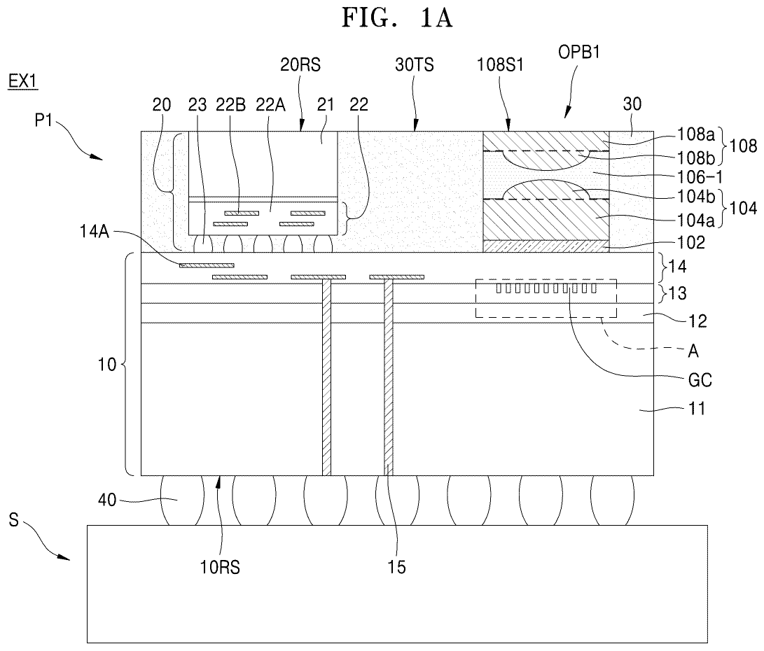

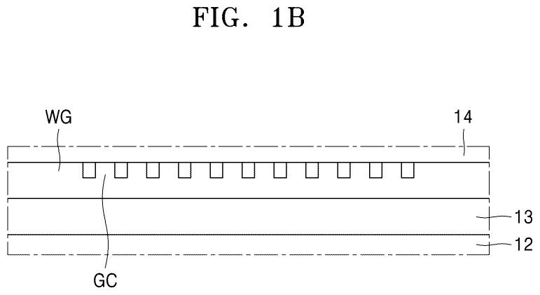

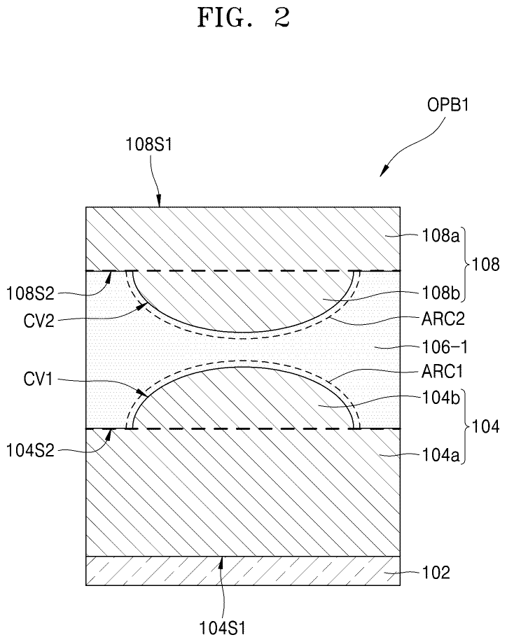

FIG. 1A is a cross-sectional view showing a semiconductor package according to an embodiment, FIG. 1B is an enlarged view of a portion A of FIG. 1A, and FIG. 2 is an enlarged view for describing an optical block of FIG. 1A.

In detail, a semiconductor package EX1 may include a package substrate S and a package structure P1 mounted on the package substrate S. The package structure P1 may be electrically connected to the package substrate S. The package substrate S may be a printed circuit board (PCB). The semiconductor package EX1 may mean the package structure P1 in a narrow sense.

The package structure P1 may include a photonic integrated circuit (PIC) die 10, an electrical integrated circuit (EIC) die 20, an optical block OPB1, and a molding layer 30.

The EIC die 20 may be mounted on the PIC die 10. The EIC die 20 may be electrically connected to the PIC die 10. The molding layer 30 may mold side surfaces and a bottom surface of the EIC die 20. In some embodiments, the PIC die 10 may include a logic die such as a central processing unit or a microcontroller, a system-on-chip die, or a combination thereof.

In some embodiments, the PIC die 10 may include a semiconductor substrate 11, a dielectric layer 12, and a light-guiding layer 13. The semiconductor substrate 11 may be a substrate including a semiconductor material. The semiconductor substrate 11 may be a bulk silicon substrate or a silicon germanium substrate.

The semiconductor substrate 11 may include a conductive layer, a transistor, a diode, a resistor, a capacitor, or a semiconductor element. In some embodiments, the dielectric layer 12 may be formed on the semiconductor substrate 11. The dielectric layer 12 may include silicon oxide, silicon nitride, or silicon oxynitride.

The light-guiding layer 13 may be formed on the dielectric layer 12. The light-guiding layer 13 may be configured to transmit an optical signal. The light-guiding layer 13 may include a grating coupler GC and an optical waveguide WG. The optical waveguide WG arranged within the light-guiding layer 13 may be optically connected to the grating coupler GC. The grating coupler GC may operate as an optical input/output apparatus of the PIC die 10.

The grating coupler GC may be provided to transmit an optical signal between the light-guiding layer 13 and an external optical element (for example, an optical fiber) through the optical block OPB1. The optical waveguide WG or the grating coupler GC of the light-guiding layer 13 may include silicon or other semiconductor materials in addition to silicon.

The PIC die 10 may include various apparatuses or circuits capable of processing and transmitting optical signals or electrical signals. The PIC die 10 may also be referred to as an optoelectronic integrated circuit die.

In some embodiments, the PIC die 10 may further include a wiring structure 14 and a through via 15. The wiring structure 14 may include a wiring layer 14A. The wiring structure 14 may be arranged on the light-guiding layer 13.

The wiring layer 14A of the wiring structure 14 may be electrically connected to the through via 15. The wiring structure 14 may be electrically connected to the conductive layer formed within the semiconductor substrate 11 or to other semiconductor devices.

In some embodiments, the EIC die 20 may include a logic die such as a central processing unit or a microcontroller, a memory die such as dynamic random access memory (DRAM) or static random access memory (SRAM), a power management die such as a power management integrated circuit (PMIC), a radio frequency (RF) die, a micro-electro-mechanical-system (MEMS) die, a signal processing die such as a digital signal processing (DSP) device, a system-on-chip die, or a combination thereof.

In some embodiments, the EIC die 20 may include a semiconductor substrate 21 and a wiring structure 22 arranged on the semiconductor substrate 21. The semiconductor substrate 21 may be a substrate including a semiconductor material. The semiconductor substrate 21 may be a bulk silicon substrate or a silicon germanium substrate. The semiconductor substrate 21 may include a conductive layer, a transistor, a diode, a resistor, a capacitor, or a semiconductor element.

The wiring structure 22 may be electrically connected to the conductive layer formed within the semiconductor substrate 21 or to other semiconductor devices. The wiring structure 22 may include a dielectric layer 22A and a wiring layer 22B formed within the dielectric layer 22A.

In some embodiments, the EIC die 20 may be electrically connected to the PIC die 10 through a plurality of electrical terminals 23. The electrical terminals 23 may be micro bumps, ball grid array (BGA) connectors, solder balls, or metal pillars.

The optical block OPB1 may be mounted and aligned with the grating coupler GC on the light-guiding layer 13 of the PIC die 10. The optical block OPB1 may be spaced apart from the EIC die 20 in a horizontal direction.

The molding layer 30 may be formed to mold the EIC die 20 and the optical block OPB1. The molding layer 30 may mold side surfaces of the EIC die 20 and the optical block OPB1.

A top surface 108S1 of the optical block OPB1, that is, the top surface 108S1 of an upper lens support portion 108a, may not protrude beyond a top surface 30TS of the molding layer 30 and may be coplanar with the top surface 30TS of the molding layer 30. A bottom surface 20RS of the EIC die 20, the top surface 30TS of the molding layer 30, and the top surface 108S1 of the optical block OPB1 may be coplanar with each other.

In some embodiments, the molding layer 30 may include a base material and filler particles distributed within the base material. The base material may include epoxy resin, phenol resin, or silicone-containing resin. The filler particles may include silica, alumina, zinc oxide, or titanium oxide.

In some embodiments, the optical block OPB1 may be bonded to the PIC die 10 by an optical glue layer 102. In some embodiments, the optical block OPB1 may be bonded to the PIC die 10 through fusion bonding. The bonding between the optical block OPB1 and the PIC die 10 is not limited to the foregoing example and may be achieved using various bonding methods.

The optical block OPB1 may include multilayer lenses 104 and 108 and an intermediate lens layer 106-1 which is located between the multilayer lenses 104 and 108 and bonds the multilayer lenses 104 and 108 together. The multilayer lenses 104 and 108 may include the lower lens 104 and the upper lens 108. The multilayer lenses 104 and 108 may include a combination of convex lenses.

In some embodiments, the multilayer lenses 104 and 108 may include glass or silicone. In some embodiments, the intermediate lens layer 106-1 may include a material having the same refractive index as each of the multilayer lenses 104 and 108.

In some embodiments, the multilayer lenses 104 and 108 may include materials having different refractive indices from each other. For example, the lower lens 104 may include glass, and the upper lens 108 may include silicone. When the multilayer lenses 104 and 108 are configured to have different refractive indices from each other, polarization or focusing of light incident through the optical block OPB1 may be adjusted, thereby further increasing the alignment margin between the optical block OPB1 and the grating coupler GC of the PIC die 10.

The lower lens 104 may include a lower lens support portion 104a bonded to the optical glue layer 102 and a lower lens core portion 104b located on the lower lens support portion 104a. The lower lens core portion 104b may have a curvature CV1 protruding outward from the lower lens support portion 104a. The lower lens 104 may be a convex lens. In some embodiments, the lower lens support portion 104a and the lower lens core portion 104b may be formed as a single body.

In some embodiments, the lower lens support portion 104a and the lower lens core portion 104b may be formed as separate bodies. The lower lens support portion 104a may include a bottom surface 104S1 bonded to the optical glue layer 102 and a top surface 104S2 bonded to the lower lens core portion 104b and the intermediate lens layer 106-1.

Because the bottom surface 104S1 of the lower lens support portion 104a is flat, the optical block OPB1 may improve bonding accuracy with the optical glue layer 102 and may be easily bonded to the optical glue layer 102.

The upper lens 108 may include: the upper lens support portion 108a bonded onto the lower lens core portion 104b by the intermediate lens layer 106-1 and an upper lens core portion 108b located on the upper lens support portion 108a.

The upper lens core portion 108b may be arranged to face the lower lens core portion 104b. In some embodiments, the upper lens core portion 108b may have a curvature CV2 protruding outward from the upper lens support portion 108a. The curvature CV2 of the upper lens core portion 108b may be different from the curvature CV1 of the lower lens core portion 104b. The upper lens 108 may be a convex lens.

In some embodiments, the upper lens support portion 108a and the upper lens core portion 108b may be formed as a single body. In some embodiments, the upper lens support portion 108a and the upper lens core portion 108b may be formed as separate bodies.

The upper lens support portion 108a may include the top surface 108S1 exposed to the outside and a bottom surface 108S2 bonded to the intermediate lens layer 106-1 and the upper lens core portion 108b. The top surface 108S1 of the upper lens support portion 108a is flat and thus may easily receive light from an optical fiber array.

Each of the optical glue layer 102 and the intermediate lens layer 106-1 may include a material capable of easily transmitting an optical signal to the grating coupler GC. In some embodiments, the optical glue layer 102 and the intermediate lens layer 106-1 may include an ultraviolet curing optical adhesive.

In some embodiments, the optical glue layer 102 and the intermediate lens layer 106-1 may include epoxy resin, silicone resin, silane resin, or acrylate resin, as well as filler particles or a curing agent added thereto. In some embodiments, the intermediate lens layer 106-1 may include silicon oxide (SiO₂) or silicon carbon nitride (SiCN).

In some embodiments, anti-reflection layers ARC1 and ARC2 may be arranged above the lower lens core portion 104b or above the upper lens core portion 108b. In some embodiments, the anti-reflection layers ARC1 and ARC2 may include magnesium fluoride (MgF₂).

In this case, polarization or focusing of light incident through the optical block OPB1 may be adjusted, thereby further increasing the alignment margin between the optical block OPB1 and the grating coupler GC of the PIC die 10.

The package structure P1 may include a plurality of electrical terminals 40. The electrical terminals 40 may be arranged on a bottom surface 10RS of the PIC die 10. The electrical terminals 40 may be electrically connected to the through via 15 of the PIC die 10. The electrical terminals 40 may be micro bumps, controlled collapse chip connection (C4) bumps, BGA connectors, solder balls, or metal pillars.

In some embodiments, the electrical terminals 40 may be electrically connected to the through via 15 of the PIC die 10 through a redistribution circuit between the PIC die 10 and the electrical terminals 40. FIG. 1A illustrates the semiconductor package EX1 as an example according to inventive concept, and the inventive concept is not limited thereto.

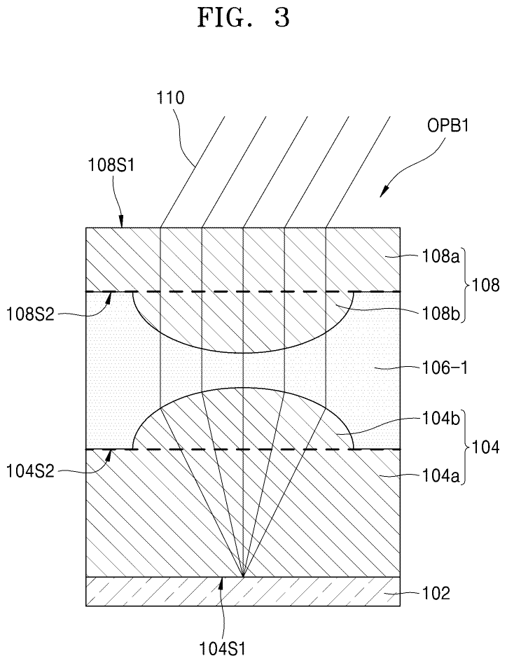

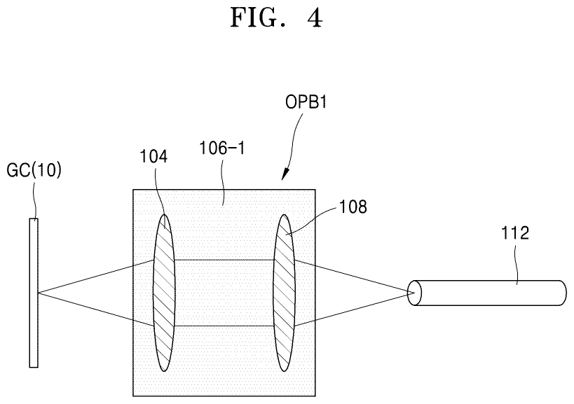

FIG. 3 is diagram for describing a path of light incident on the optical block of FIG. 1A, and FIG. 4 is a diagram for describing a path of light incident on a grating coupler of a PIC die through the optical block of FIG. 1A.

In detail, in FIGS. 3 and 4, the same reference numerals as those in FIGS. 1A and 2 denote the same components. For FIGS. 3 and 4, descriptions provided with reference to FIGS. 1A and 2 are briefly provided.

As shown in FIG. 3, light 110 emitted from an optical fiber array 112 (of FIG. 4) may be incident on the optical block OPB1 including the multilayer lenses 104 and 108. The light 110 emitted from the optical fiber array 112 may be incident on the upper lens 108 of the optical block OPB1 with a sufficient amount of light.

The light incident on the upper lens 108 of the optical block OPB1 travels vertically to the lower lens 104. The light 110 that has passed through the lower lens 104 may be incident on the optical glue layer 102.

For convenience of explanation, FIG. 4 shows that the upper lens 108 and the lower lens 104 of the optical block OPB1 are vertically arranged. The light 110 emitted from the optical fiber array 112 may be incident on the upper lens 108 of the optical block OPB1. The light 110 incident on the upper lens 108 of the optical block OPB1 travels vertically to the lower lens 104. The arrangements of the upper lens 108 and the lower lens 104 and the traveling of the incident lights are not limited to the foregoing examples.

The light 110 that has passed through the lower lens 104 may be incident on the grating coupler GC of the PIC die 10. When the optical block OPB1 includes the multilayer lenses 104 and 108, the light 110 emitted from the optical fiber array 112 (of FIG. 4) may be expanded, and polarization or focusing of the light 110 may be adjusted.

Accordingly, the alignment margin between the optical block OPB1 and the grating coupler GC of the PIC die 10 may be increased, and insertion loss of light incident through the optical block OPB1 may be reduced.

As described above, the semiconductor package EX1 shown in FIGS. 1A to 4 may include the EIC die 20 and the optical block OPB1, which are mounted on the PIC die 10, and the molding layer 30 for molding the EIC die 20 and the optical block OPB1.

The bottom surface 104S1 of the lower lens support portion 104a and the top surface 108S1 of the upper lens support portion 108a, which constitute the optical block OPB1, may be flat. Accordingly, the optical block OPB1 may improve bonding accuracy with the optical glue layer 102 and may facilitate a planarization process for forming the molding layer 30 during manufacturing.

In addition, the optical block OPB1 included in the semiconductor package EX1 of the inventive concept shown in FIGS. 1A to 4 includes the multilayer lenses 104 and 108, thereby enabling expansion of the light 110 emitted from the optical fiber array 112 and adjustment of polarization or focusing of the light 110.

Accordingly, the semiconductor package EX1 may increase the alignment margin between the optical block OPB1 and the grating coupler GC of the PIC die 10 and may reduce insertion loss of light incident through the optical block OPB1.

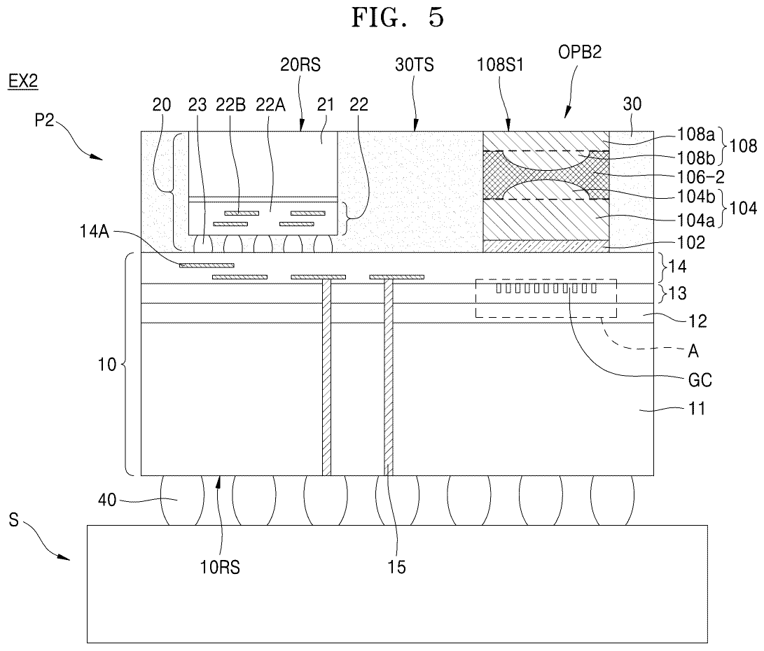

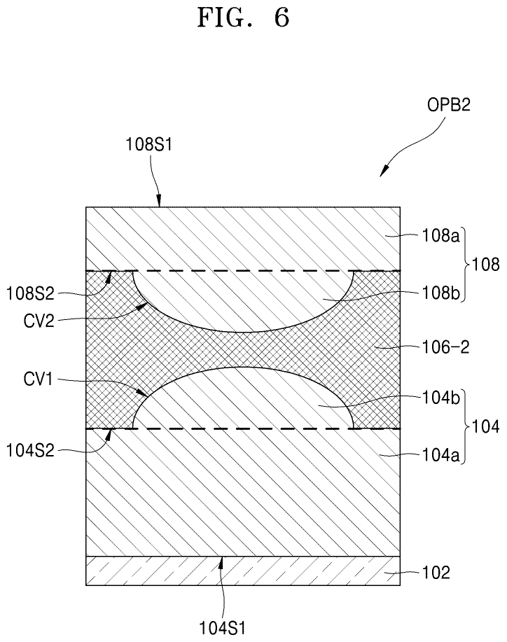

FIG. 5 is a cross-sectional view showing a semiconductor package according to an embodiment, and FIG. 6 is an enlarged view for describing an optical block of FIG. 5.

In detail, a semiconductor package EX2 may be the same as that shown in FIGS. 1A to 4, except that an optical block OPB2 of a package structure P2 includes an intermediate lens layer 106-2. In FIGS. 5 and 6, the same or similar reference numerals as those in FIGS. 1A to 4 denote the same or similar components. For FIGS. 5 and 6, descriptions provided with reference to FIGS. 1A to 4 are briefly provided or omitted.

The semiconductor package EX2 may include the package substrate S and the package structure P2 mounted on the package substrate S. The package structure P2 may include the PIC die 10, the EIC die 20, the optical block OPB2, and the molding layer 30.

The top surface 108S1 of the optical block OPB2, that is, the top surface 108S1 of the upper lens support portion 108a, may not protrude beyond the top surface 30TS of the molding layer 30 and may be coplanar with the top surface 30TS of the molding layer 30. The bottom surface 20RS of the EIC die 20, the top surface 30TS of the molding layer 30, and the top surface 108S1 of the optical block OPB2 may be coplanar with each other.

The optical block OPB2 may be bonded to the PIC die 10 by the optical glue layer 102. The optical block OPB2 may include the multilayer lenses 104 and 108 and the intermediate lens layer 106-2 which is located between the multilayer lenses 104 and 108 and bonds the multilayer lenses 104 and 108 together.

In some embodiments, the multilayer lenses 104 and 108 may include glass or silicone. In some embodiments, the intermediate lens layer 106-2 may include a material having a different refractive index from each of the multilayer lenses 104 and 108. For example, the refractive index of the intermediate lens layer 106-2 may be greater than the refractive index of each of the multilayer lenses 104 and 108.

When the refractive index of the intermediate lens layer 106-2 is different from the refractive index of each of the multilayer lenses 104 and 108, polarization or focusing of light incident through the optical block OPB2 may be adjusted, thereby further increasing the alignment margin between the optical block OPB2 and the grating coupler GC of the PIC die 10.

In some embodiments, the multilayer lenses 104 and 108 may include materials having different refractive indices from each other. When the multilayer lenses 104 and 108 are configured to have different refractive indices from each other, polarization or focusing of light incident through the optical block OPB2 may be adjusted, thereby further increasing the alignment margin between the optical block OPB2 and the grating coupler GC of the PIC die 10.

The multilayer lenses 104 and 108 may include the lower lens 104 and the upper lens 108. The lower lens 104 may include the lower lens support portion 104a and the lower lens core portion 104b. The lower lens core portion 104b may have the curvature CV1.

The lower lens support portion 104a may include the bottom surface 104S1 bonded to the optical glue layer 102 and the top surface 104S2 bonded to the lower lens core portion 104b and the intermediate lens layer 106-2. Because the bottom surface 104S1 of the lower lens support portion 104a is flat, the optical block OPB2 may improve bonding accuracy with the optical glue layer 102 and may be easily bonded to the optical glue layer 102.

The upper lens 108 may include the upper lens support portion 108a bonded onto the lower lens core portion 104b by the intermediate lens layer 106-2 and the upper lens core portion 108b located on the upper lens support portion 108a.

The upper lens support portion 108a may include the top surface 108S1 exposed to the outside and the bottom surface 108S2 bonded to the intermediate lens layer 106-2 and the upper lens core portion 108b. The top surface 108S1 of the upper lens support portion 108a is flat and thus may easily receive light from the optical fiber array.

Each of the optical glue layer 102 and the intermediate lens layer 106-2 may include a material capable of easily transmitting an optical signal to the grating coupler GC. In some embodiments, the optical glue layer 102 and the intermediate lens layer 106-2 may include an ultraviolet curing optical adhesive.

In some embodiments, the optical glue layer 102 and the intermediate lens layer 106-2 may include epoxy resin, silicone resin, silane resin, or acrylate resin, as well as filler particles or a curing agent added thereto.

The intermediate lens layer 106-2 may be configured to have a different refractive index than each of the multilayer lenses 104 and 108 by adjusting the types of the aforementioned materials or the amount of additives such as filler particles or a curing agent during manufacturing.

The package structure P2 may include the plurality of electrical terminals 40. The electrical terminals 40 may be arranged on the bottom surface 10RS of the PIC die 10. The electrical terminals 40 may be electrically connected to the through via 15 of the PIC die 10.

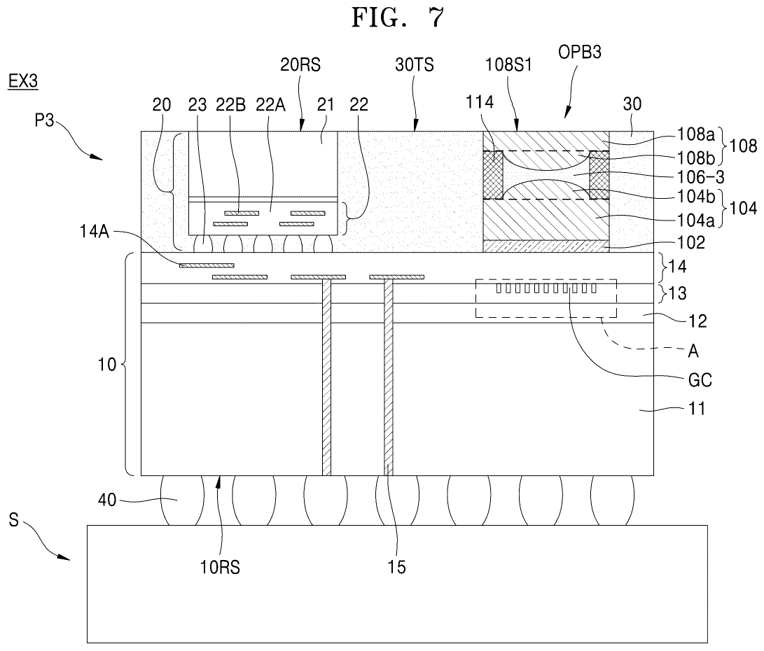

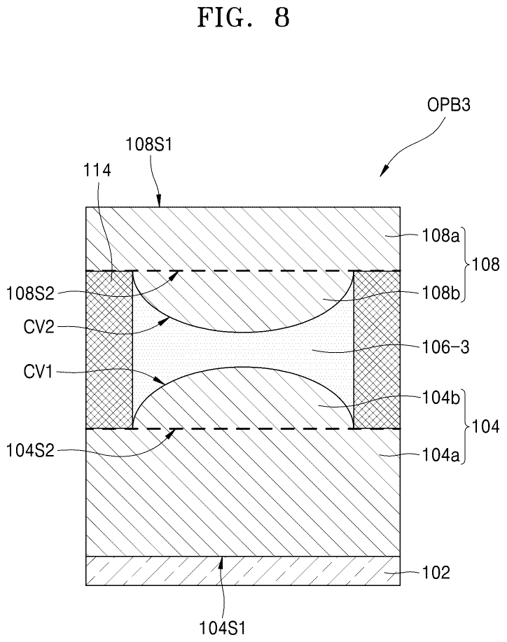

FIG. 7 is a cross-sectional view showing a semiconductor package according to an embodiment, and FIG. 8 is an enlarged view for describing an optical block of FIG. 7.

In detail, a semiconductor package EX3 may be the same as that shown in FIGS. 1A to 4, except that an optical block OPB3 of a package structure P3 includes an intermediate lens layer 106-3 and lens bridges 114. In FIGS. 7 and 8, the same or similar reference numerals as those in FIGS. 1A to 4 denote the same or similar components. For FIGS. 7 and 8, descriptions provided with reference to FIGS. 1A to 4 are briefly provided or omitted.

The semiconductor package EX3 may include the package substrate S and the package structure P3 mounted on the package substrate S. The package structure P3 may include the PIC die 10, the EIC die 20, the optical block OPB3, and the molding layer 30.

The top surface 108S1 of the optical block OPB3, that is, the top surface 108S1 of the upper lens support portion 108a, may not protrude beyond the top surface 30TS of the molding layer 30 and may be coplanar with the top surface 30TS of the molding layer 30. The bottom surface 20RS of the EIC die 20, the top surface 30TS of the molding layer 30, and the top surface 108S1 of the optical block OPB3 may be coplanar with each other.

The optical block OPB3 may be bonded to the PIC die 10 by the optical glue layer 102. The optical block OPB3 may include the multilayer lenses 104 and 108, the intermediate lens layer 106-3 located between the multilayer lenses 104 and 108, and the lens bridges 114 located on opposite sides of the intermediate lens layer 106-3 and in contact with the molding layer 30. The intermediate lens layer 106-3 and the lens bridges 114 may be configured to be in contact with and bonded to the multilayer lenses 104 and 108.

In some embodiments, the multilayer lenses 104 and 108 may include glass or silicone. In some embodiments, the intermediate lens layer 106-3 and the lens bridges 114 may include materials having different refractive indices from each other.

When the intermediate lens layer 106-3 and the lens bridges 114 are configured to have different refractive indices from each other, polarization or focusing of light incident through the optical block OPB3 may be adjusted (or stray lights may be suppressed), thereby further increasing the alignment margin between the optical block OPB3 and the grating coupler GC of the PIC die 10.

In some embodiments, the lens bridges 114 may be configured in the form of films. When the lens bridges 114 are configured in the form of films, the multilayer lenses 108 may be easily bonded to the multilayer lenses 104, and a distance between the multilayer lenses 104 and 108 may be easily adjusted.

In some embodiments, the lens bridges 114 may further include a light absorber or a light reflector. In this case, polarization or focusing of light incident through the optical block OPB3 may be adjusted, thereby further increasing the alignment margin between the optical block OPB3 and the grating coupler GC of the PIC die 10.

The multilayer lenses 104 and 108 may include: the lower lens 104 bonded to the PIC die 10; and the upper lens 108 spaced apart from the lower lens 104 by the intermediate lens layer 106-3 and the lens bridges 114.

The lower lens 104 may include the lower lens support portion 104a bonded to the PIC die 10 and the lower lens core portion 104b located on the lower lens support portion 104a. The lower lens core portion 104b may have the curvature CV1.

The lower lens support portion 104a may include the bottom surface 104S1 bonded to the optical glue layer 102 and the top surface 104S2 bonded to the lower lens core portion 104b and the lens bridges 114. Because the bottom surface 104S1 of the lower lens support portion 104a is flat, the optical block OPB3 may improve bonding accuracy with the optical glue layer 102 and may be easily bonded to the optical glue layer 102.

The upper lens 108 may include the upper lens core portion 108b and the upper lens support portion 108a located on the upper lens core portion 108b and the lens bridges 114, the upper lens core portion 108b being spaced apart from the lower lens core portion 104b by the intermediate lens layer 106-3 and positioned to face the lower lens core portion 104b.

The upper lens support portion 108a may include the top surface 108S1 exposed to the outside and the bottom surface 108S2 bonded to the intermediate lens layer 106-3, the upper lens core portion 108b, and the lens bridges 114. The top surface 108S1 of the upper lens support portion 108a is flat and thus may easily receive light from the optical fiber array.

Each of the optical glue layer 102, the intermediate lens layer 106-3, and the lens bridges 114 may include a material capable of easily transmitting an optical signal to the grating coupler GC. In some embodiments, the optical glue layer 102, the intermediate lens layer 106-3, and the lens bridges 114 may include an ultraviolet curing optical adhesive.

In some embodiments, the optical glue layer 102, the intermediate lens layer 106-3, and the lens bridges 114 may include epoxy resin, silicone resin, silane resin, or acrylate resin, as well as filler particles or a curing agent added thereto.

The intermediate lens layer 106-3 and the lens bridges 114 may be configured to have different refractive indices from each other by adjusting the types of the aforementioned materials or the amount of additives such as filler particles or a curing agent during manufacturing.

The package structure P3 may include the plurality of electrical terminals 40. The electrical terminals 40 may be arranged on the bottom surface 10RS of the PIC die 10. The electrical terminals 40 may be electrically connected to the through via 15 of the PIC die 10.

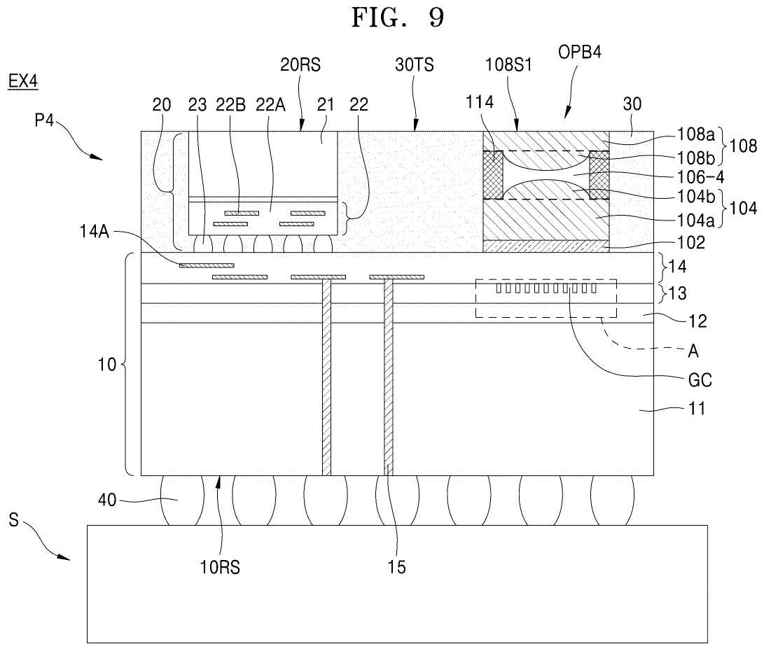

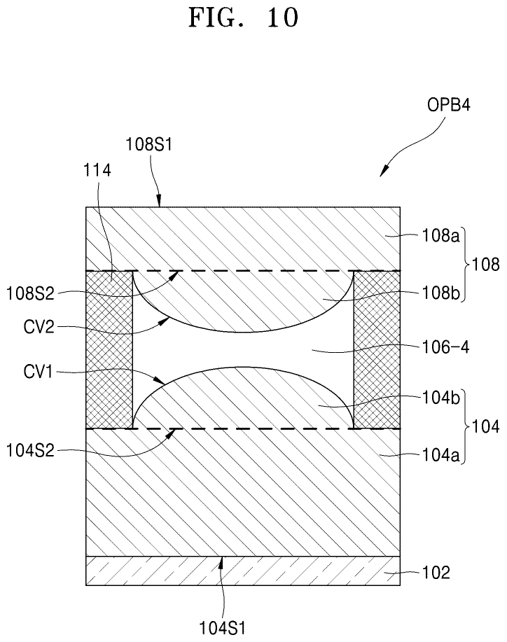

FIG. 9 is a cross-sectional view showing a semiconductor package according to an embodiment, and FIG. 10 is an enlarged view for describing an optical block of FIG. 9.

In detail, a semiconductor package EX4 may be the same as that shown in FIGS. 1A to 4, except that an optical block OPB4 of a package structure P4 includes an intermediate lens layer 106-4 and the lens bridges 114. In FIGS. 9 and 10, the same or similar reference numerals as those in FIGS. 1A to 4 denote the same or similar components. For FIGS. 9 and 10, descriptions provided with reference to FIGS. 1A to 4 are briefly provided or omitted.

The semiconductor package EX4 may include the package substrate S and the package structure P4 mounted on the package substrate S. The package structure P4 may include the PIC die 10, the EIC die 20, the optical block OPB4, and the molding layer 30.

The top surface 108S1 of the optical block OPB4, that is, the top surface 108S1 of the upper lens support portion 108a, may not protrude beyond the top surface 30TS of the molding layer 30 and may be coplanar with the top surface 30TS of the molding layer 30. The bottom surface 20RS of the EIC die 20, the top surface 30TS of the molding layer 30, and the top surface 108S1 of the optical block OPB4 may be coplanar with each other.

The optical block OPB4 may be bonded to the PIC die 10 by the optical glue layer 102. The optical block OPB4 may include the multilayer lenses 104 and 108, the intermediate lens layer 106-4 located between the multilayer lenses 104 and 108, and the lens bridges 114 located on opposite sides of the intermediate lens layer 106-4 and in contact with the molding layer 30. The lens bridges 114 may be configured to be in contact with and bonded to the multilayer lenses 104 and 108.

In some embodiments, the multilayer lenses 104 and 108 may include glass or silicone. In some embodiments, the intermediate lens layer 106-4 and the lens bridges 114 may include materials having different refractive indices from each other. In some embodiments, the intermediate lens layer 106-4 may be formed as an air layer.

When the intermediate lens layer 106-4 and the lens bridges 114 are configured to have different refractive indices from each other, polarization or focusing of light incident through the optical block OPB4 may be adjusted, thereby further increasing the alignment margin between the optical block OPB4 and the grating coupler GC of the PIC die 10.

In some embodiments, the lens bridges 114 may be configured in the form of films. When the lens bridges 114 are configured in the form of films, the multilayer lenses 104 and 108 may be easily bonded to each other, and a distance between the multilayer lenses 104 and 108 may be easily adjusted.

In some embodiments, the lens bridges 114 may further include a light absorber or a light reflector. In this case, polarization or focusing of light incident through the optical block OPB4 may be adjusted, thereby further increasing the alignment margin between the optical block OPB4 and the grating coupler GC of the PIC die 10.

The multilayer lenses 104 and 108 may include: the lower lens 104 bonded to the PIC die 10; and the upper lens 108 spaced apart from the lower lens 104 by the intermediate lens layer 106-4 and the lens bridges 114.

The lower lens 104 may include the lower lens support portion 104a bonded to the PIC die 10 and the lower lens core portion 104b located on the lower lens support portion 104a. The lower lens core portion 104b may have the curvature CV1.

The lower lens support portion 104a may include the bottom surface 104S1 bonded to the optical glue layer 102 and the top surface 104S2 bonded to the lower lens core portion 104b and the lens bridges 114. Because the bottom surface 104S1 of the lower lens support portion 104a is flat, the optical block OPB4 may improve bonding accuracy with the optical glue layer 102 and may be easily bonded to the optical glue layer 102.

The upper lens 108 may include the upper lens core portion 108b and the upper lens support portion 108a located on the upper lens core portion 108b and the lens bridges 114, the upper lens core portion 108b being spaced apart from the lower lens core portion 104b by the intermediate lens layer 106-4 and positioned to face the lower lens core portion 104b.

The upper lens support portion 108a may include the top surface 108S1 exposed to the outside and the bottom surface 108S2 bonded to the lens bridges 114. The top surface 108S1 of the upper lens support portion 108a is flat and thus may easily receive light from the optical fiber array.

Each of the optical glue layer 102 and the lens bridges 114 may include a material capable of easily transmitting an optical signal to the grating coupler GC. In some embodiments, the optical glue layer 102 and the lens bridges 114 may include an ultraviolet curing optical adhesive.

In some embodiments, the optical glue layer 102, the intermediate lens layer 106-4, and the lens bridges 114 may include epoxy resin, silicone resin, silane resin, or acrylate resin, as well as filler particles or a curing agent added thereto. A refractive index of the lens bridges 114 may be controlled by adjusting the types of the aforementioned materials or the amount of additives such as filler particles or a curing agent during manufacturing.

The package structure P4 may include the plurality of electrical terminals 40. The electrical terminals 40 may be arranged on the bottom surface 10RS of the PIC die 10. The electrical terminals 40 may be electrically connected to the through via 15 of the PIC die 10.

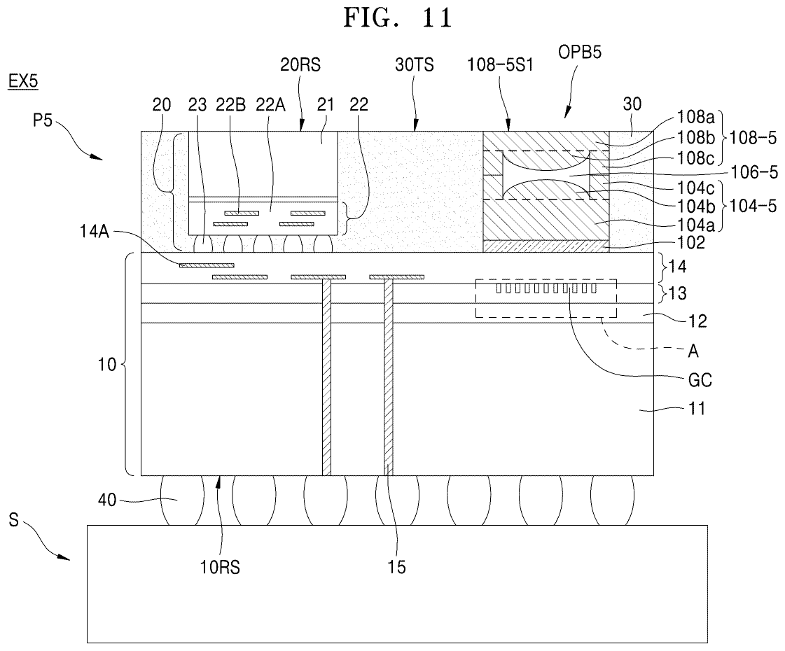

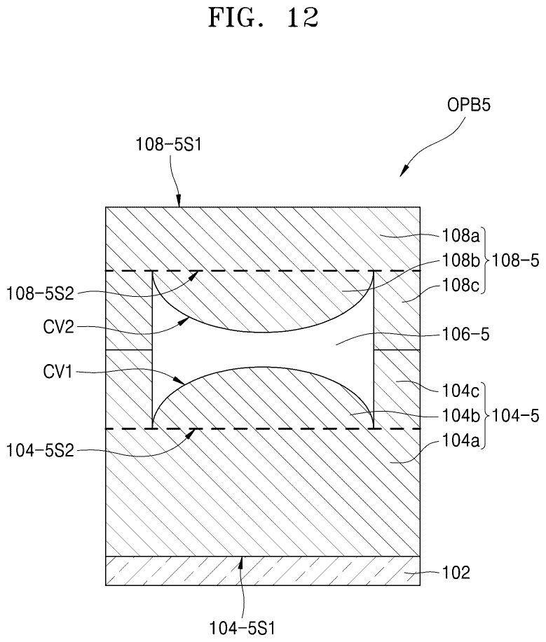

FIG. 11 is a cross-sectional view showing a semiconductor package according to an embodiment, and FIG. 12 is an enlarged view for describing an optical block of FIG. 11.

In detail, a semiconductor package EX5 may be the same as that shown in FIGS. 1A to 4, except that an optical block OPB5 of a package structure P5 includes an intermediate lens layer 106-5, a lower lens bridge 104c, and an upper lens bridge 108c.

The semiconductor package EX5 may be the same as that shown in FIGS. 9 and 10, except that the lens bridges 114 include the lower lens bridge 104c and the upper lens bridge 108c.

In FIGS. 11 and 12, the same or similar reference numerals as those in FIGS. 1A to 4, 9, and 11 denote the same or similar components. For FIGS. 11 and 12, descriptions provided with reference to FIGS. 1A to 4, 9, and 11 are briefly provided or omitted.

The semiconductor package EX5 may include the package substrate S and the package structure P5 mounted on the package substrate S. The package structure P5 may include the PIC die 10, the EIC die 20, the optical block OPB5, and the molding layer 30.

A top surface 108-5S1 of the optical block OPB5, that is, the top surface 108-5S1 of the upper lens support portion 108a, may not protrude beyond the top surface 30TS of the molding layer 30 and may be coplanar with the top surface 30TS of the molding layer 30. The bottom surface 20RS of the EIC die 20, the top surface 30TS of the molding layer 30, and the top surface 108-5S1 of the optical block OPB5 may be coplanar with each other.

The optical block OPB5 may be bonded to the PIC die 10 by the optical glue layer 102. The optical block OPB5 may include multilayer lenses 104-5 and 108-5 and the intermediate lens layer 106-5 located between the multilayer lenses 104-5 and 108-5.

The multilayer lenses 104-5 and 108-5 may respectively include the lower lens bridge 104c and the upper lens bridge 108c, which are each located on opposite sides of the intermediate lens layer 106-5 and in contact with the molding layer 30. The lower lens bridge 104c and the upper lens bridge 108c may respectively be in contact with and bonded to the lower lens support portion 104a and the upper lens support portion 108a.

In some embodiments, the multilayer lenses 104-5 and 108-5 may include glass or silicone. In some embodiments, the intermediate lens layer 106-5 may be formed as an air layer. The intermediate lens layer 106-5 may have a different refractive index from each of the multilayer lenses 104-5 and 108-5.

When the refractive index of the intermediate lens layer 106-5 is different from the refractive index of each of the multilayer lenses 104-5 and 108-5, polarization or focusing of light incident through the optical block OPB5 may be adjusted, thereby further increasing the alignment margin between the optical block OPB5 and the grating coupler GC of the PIC die 10.

In some embodiments, the lower lens bridge 104c and the upper lens bridge 108c may be configured in the form of a film. When the lower lens bridge 104c and the upper lens bridge 108c are configured in the form of a film, the multilayer lenses 104-5 and 108-5 may be easily bonded to each other and a distance between the multilayer lenses 104-5 and 108-5 may be easily adjusted.

In some embodiments, the lens bridges 104c and 108c may further include a light absorber or a light reflector. In this case, polarization or focusing of light incident through the optical block OPB5 may be adjusted, thereby further increasing the alignment margin between the optical block OPB5 and the grating coupler GC of the PIC die 10.

The multilayer lenses 104-5 and 108-5 may include: the lower lens 104-5 bonded to the PIC die 10; and the upper lens 108-5 spaced apart from the lower lens 104-5 by the intermediate lens layer 106-5 and the lens bridges 104c and 108c.

The lower lens 104-5 may include the lower lens support portion 104a bonded to the PIC die 10, the lower lens core portion 104b located on the lower lens support portion 104a, and the lower lens bridge 104c located on opposite sides of the intermediate lens layer 106-5. The lower lens support portion 104a, the lower lens core portion 104b, and the lower lens bridge 104c may be formed as a single body. The lower lens core portion 104b may have the curvature CV1.

The lower lens support portion 104a may include a bottom surface 104-5S1 bonded to the optical glue layer 102 and a top surface 104-5S2 bonded to the lower lens core portion 104b and the lower lens bridge 104c. Because the bottom surface 104-5S1 of the lower lens support portion 104a is flat, the optical block OPB5 may improve bonding accuracy with the optical glue layer 102 and may be easily bonded to the optical glue layer 102.

The upper lens 108-5 may include: the upper lens core portion 108b which is in contact with the intermediate lens layer 106-5 located on the lower lens core portion 104b and is positioned to face the lower lens core portion 104b; the upper lens bridge 108c located on the lower lens bridge 104c; and the upper lens support portion 108a located on the upper lens core portion 108b and the upper lens bridge 108c. The lower lens bridge 104c and the upper lens bridge 108c are bonded together.

The upper lens support portion 108a may include the top surface 108-5S1 exposed to the outside and a bottom surface 108-5S2 which is in contact with the upper lens bridge 108c. The top surface 108-5S1 of the upper lens support portion 108a is flat and thus may easily receive light from the optical fiber array.

Each of the optical glue layer 102, the lower lens bridge 104c, and the upper lens bridge 108c may include a material capable of easily transmitting an optical signal to the grating coupler GC. In some embodiments, the optical glue layer 102, the lower lens bridge 104c, and the upper lens bridge 108c may include an ultraviolet curing optical adhesive.

In some embodiments, the optical glue layer 102, the lower lens bridge 104c, and the upper lens bridge 108c may include epoxy resin, silicone resin, silane resin, or acrylate resin, as well as filler particles or a curing agent added thereto.

The package structure P5 may include the plurality of electrical terminals 40. The electrical terminals 40 may be arranged on the bottom surface 10RS of the PIC die 10. The electrical terminals 40 may be electrically connected to the through via 15 of the PIC die 10.

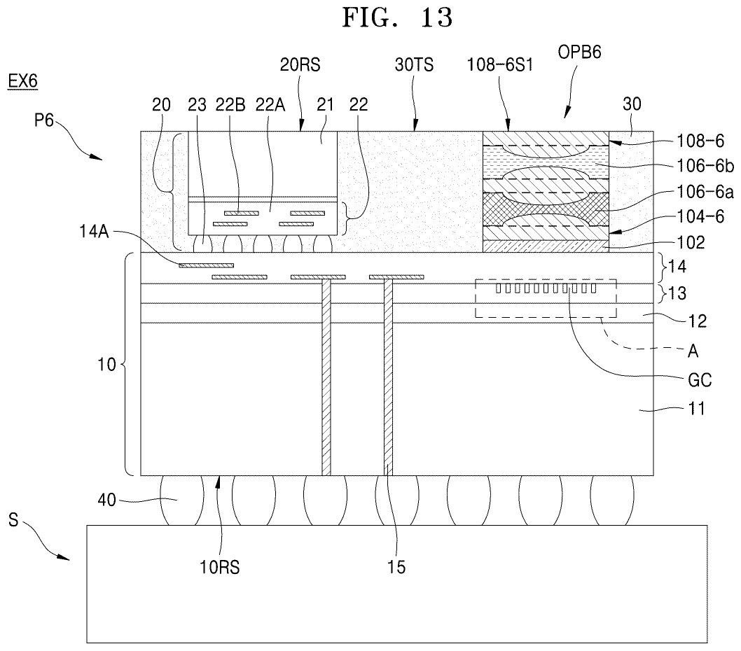

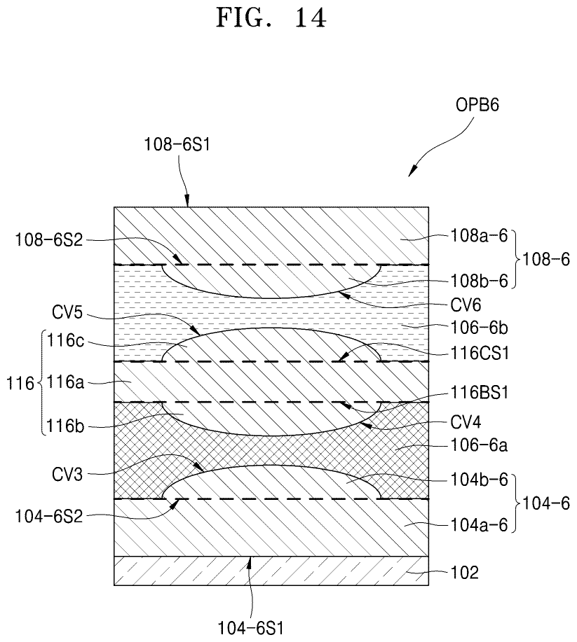

FIG. 13 is a cross-sectional view showing a semiconductor package according to an embodiment, and FIG. 14 is an enlarged view for describing an optical block of FIG. 13.

In detail, a semiconductor package EX6 may be the same as that shown in FIGS. 1A to 4, except that an optical block OPB6 of a package structure P6 includes intermediate lens layers 106-6a and 106-6b and multilayer lenses 104-6, 116, and 108-6.

In FIGS. 13 and 14, the same or similar reference numerals as those in FIGS. 1A to 4 denote the same or similar components. For FIGS. 13 and 14, descriptions provided with reference to FIGS. 1A to 4 are briefly provided or omitted.

The semiconductor package EX6 may include the package substrate S and the package structure P6 mounted on the package substrate S. The package structure P6 may include the PIC die 10, the EIC die 20, the optical block OPB6, and the molding layer 30.

A top surface 108-6S1 of the optical block OPB6, that is, the top surface 108-6S1 of an upper lens support portion 108a-6, may not protrude beyond the top surface 30TS of the molding layer 30 and may be coplanar with the top surface 30TS of the molding layer 30. The bottom surface 20RS of the EIC die 20, the top surface 30TS of the molding layer 30, and the top surface 108-6S1 of the optical block OPB6 may be coplanar with each other.

The optical block OPB6 may be bonded to the PIC die 10 by the optical glue layer 102. The optical block OPB6 may include the multilayer lenses 104-6, 116, and 108-6 and the intermediate lens layers 106-6a and 106-6b respectively located between the multilayer lenses 104-6 and 116 and between the multilayer lenses 116 and 108-6.

In some embodiments, the multilayer lenses 104-6, 116, and 108-6 may include glass or silicone. In some embodiments, each of the intermediate lens layers 106-6a and 106-6b may include a material having a different refractive index from each of the multilayer lenses 104-6, 116, and 108-6. For example, the refractive index of each of the intermediate lens layers 106-6a and 106-6b may be greater than the refractive index of each of the multilayer lenses 104-6, 116, and 108-6.

When the refractive index of each of the intermediate lens layers 106-6a and 106-6b is different from the refractive index of each of the multilayer lenses 104-6, 116, and 108-6, polarization or focusing of light incident through the optical block OPB6 may be adjusted, thereby further increasing the alignment margin between the optical block OPB6 and the grating coupler GC of the PIC die 10.

In some embodiments, the intermediate lens layers 106-6a and 106-6b may be configured to have different refractive indices from each other. In this case, polarization or focusing of light incident through the optical block OPB6 may be adjusted, thereby further increasing the alignment margin between the optical block OPB6 and the grating coupler GC of the PIC die 10.

In some embodiments, the multilayer lenses 104-6, 116, and 108-6 may include materials having different refractive indices from one another. When the multilayer lenses 104-6, 116, and 108-6 are configured to have different refractive indices from one another, polarization or focusing of light incident through the optical block OPB6 may be adjusted, thereby further increasing the alignment margin between the optical block OPB6 and the grating coupler GC of the PIC die 10.

The multilayer lenses 104-6, 116, and 108-6 may include: the lower lens 104-6 bonded to the PIC die 10; the intermediate lens 116 spaced apart from the lower lens 104-6 by the lower intermediate lens layer 106-6a; and the upper lens 108-6 spaced apart from the intermediate lens 116 by the upper intermediate lens layer 106-6b. The multilayer lenses 104-6, 116, and 108-6 may include a combination of convex lenses.

The lower lens 104-6 may include a lower lens support portion 104a-6 and a lower lens core portion 104b-6. The lower lens core portion 104b-6 may have a curvature CV3 protruding outward from the lower lens support portion 104a-6. The lower lens 104-6 may be a convex lens.

The lower lens support portion 104a-6 may include a bottom surface 104-6S1 bonded to the optical glue layer 102 and a top surface 104-6S2 bonded to the lower lens core portion 104b-6 and the intermediate lens layer 106-6a. Because the bottom surface 104-6S1 of the lower lens support portion 104a-6 is flat, the optical block OPB6 may improve bonding accuracy with the optical glue layer 102 and may be easily bonded to the optical glue layer 102.

The intermediate lens 116 may include an intermediate lens support portion 116a and intermediate lens core portions 116b and 116c. The intermediate lens support portion 116a may include a flat top surface 116CS1 and a flat bottom surface 116BS1. The intermediate lens core portions 116b and 116c may be formed under and above the intermediate lens support portion 116a, respectively.

The intermediate lens core portions 116b and 116c may include the lower intermediate lens core portion 116b and the upper intermediate lens core portion 116c. The intermediate lens support portion 116a and the lower intermediate lens core portion 116b may be in contact with the lower intermediate lens layer 106-6a.

The intermediate lens support portion 116a and the upper intermediate lens core portion 116c may be in contact with the upper intermediate lens layer 106-6b. The lower intermediate lens core portion 116b may have a curvature CV4 protruding outward from the intermediate lens support portion 116a. The lower intermediate lens core portion 116b may be a convex lens.

The upper intermediate lens core portion 116c may have a curvature CV5 protruding outward from the intermediate lens support portion 116a. The upper intermediate lens core portion 116c may be a convex lens. The intermediate lens 116 may include a combination of convex lenses.

The upper lens 108-6 may include: the upper lens support portion 108a-6 bonded onto the upper intermediate lens core portion 116c by the upper intermediate lens layer 106-6b; and an upper lens core portion 108b-6 located under the upper lens support portion 108a-6. The upper lens core portion 108b-6 may have a curvature CV6 protruding outward from the upper lens support portion 108a-6. The upper lens 108-6 may be a convex lens. In some embodiments, the curvatures CV3, CV4, CV5, and CV6 may be different from each other.

The upper lens support portion 108a-6 may include the top surface 108-6S1 exposed to the outside and the bottom surface 108-6S2 bonded to the intermediate lens layer 106-6b and the upper lens core portion 108b-6. The top surface 108-6S1 of the upper lens support portion 108a-6 is flat and thus may easily receive light from the optical fiber array.

Each of the optical glue layer 102 and the intermediate lens layers 106-6a and 106-6b may include a material capable of easily transmitting an optical signal to the grating coupler GC. In some embodiments, the optical glue layer 102 and the intermediate lens layers 106-6a and 106-6b may include an ultraviolet curing optical adhesive.

In some embodiments, the optical glue layer 102 and the intermediate lens layers 106-6a and 106-6b may include epoxy resin, silicone resin, silane resin, or acrylate resin, as well as filler particles or a curing agent added thereto.

Each of the intermediate lens layers 106-6a and 106-6b may be configured to have a different refractive index from each of the multilayer lenses 104-6, 116, and 108-6 by adjusting the types of the aforementioned materials or the amount of additives such as filler particles or a curing agent during manufacturing.

The package structure P6 may include the plurality of electrical terminals 40. The electrical terminals 40 may be arranged on the bottom surface 10RS of the PIC die 10. The electrical terminals 40 may be electrically connected to the through via 15 of the PIC die 10.

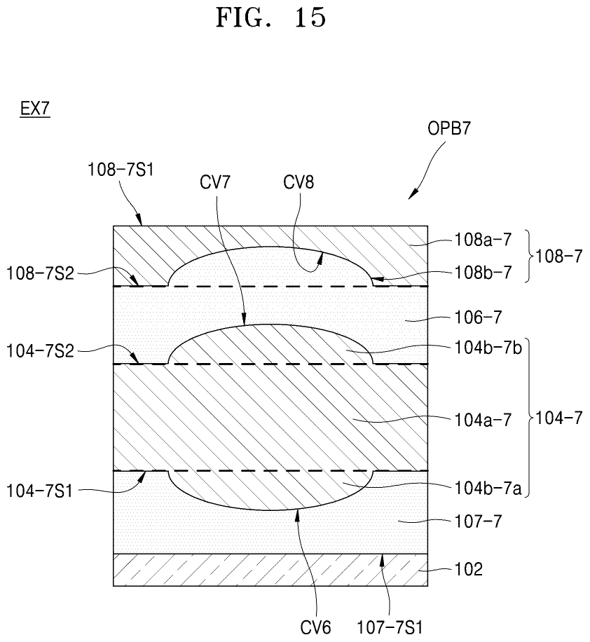

FIG. 15 is a cross-sectional view showing an optical block of a semiconductor package according to an embodiment.

In detail, a semiconductor package EX7 may include an optical block OPB7. The optical block OPB7 may replace the optical block OPB1 of the semiconductor package EX1 of FIG. 1A. In FIG. 15, the same or similar reference numerals as those in FIGS. 1A to 4 denote the same or similar components. For FIG. 15, descriptions provided with reference to FIGS. 1A to 4 are briefly provided or omitted.

The optical block OPB7 may be bonded to the PIC die 10 (of FIG. 1A) by the optical glue layer 102. The optical block OPB7 may include multilayer lenses 104-7 and 108-7, an intermediate lens layer 106-7, and a lens protective layer 107-7. The intermediate lens layer 106-7 may be located between the multilayer lenses 104-7 and 108-7 and bond the multilayer lenses 104-7 and 108-7 together. The lens protective layer 107-7 may be located under the lower lens 104-7 to protect the lower lens 104-7.

In some embodiments, the multilayer lenses 104-7 and 108-7 may include glass or silicone. In some embodiments, each of the intermediate lens layer 106-7 and the lens protective layer 107-7 may include a material having a different refractive index from each of the multilayer lenses 104-7 and 108-7. In some embodiments, the multilayer lenses 104-7 and 108-7 may include materials having different refractive indices from each other.

The multilayer lenses 104-7 and 108-7 may include the lower lens 104-7 and the upper lens 108-7. The multilayer lenses 104-7 and 108-7 may include a combination of convex lenses and a concave lens.

The lower lens 104-7 may include a lower lens support portion 104a-7 and lower lens core portions 104b-7a and 104b-7b. The lower lens support portion 104a-7 may be a flat plate-type lens. The lower lens core portions 104b-7a and 104b-7b may include the first lower lens core portion 104b-7a and the second lower lens core portion 104b-7b respectively located on a bottom surface 104-7S1 and a top surface 104-7S2 of the lower lens support portion 104a-7.

The first lower lens core portion 104b-7a and the second lower lens core portion 104b-7b may respectively have the curvature CV6 and a curvature CV7, each protruding outward from the lower lens support portion 104a-7. The first lower lens core portion 104b-7a and the second lower lens core portion 104b-7b may be convex lenses. The lower lens 104-7 may include a combination of convex lenses.

The lower lens support portion 104a-7 may include the bottom surface 104-7S1 bonded to the lens protective layer 107-7 and the first lower lens core portion 104b-7a and the top surface 104-7S2 bonded to the second lower lens core portion 104b-7b and the intermediate lens layer 106-7. The lens protective layer 107-7 may have a bottom surface 107-7S1 bonded to the optical glue layer 102. Because the bottom surface 107-7S1 of the lens protective layer 107-7 is flat, the optical block OPB7 may improve bonding accuracy with the optical glue layer 102 and may be easily bonded to the optical glue layer 102.

The upper lens 108-7 may be bonded onto the lower lens support portion 104a-7 and the second lower lens core portion 104b-7b by the intermediate lens layer 106-7. The upper lens 108-7 may include an upper lens support portion 108a-7 and a concave portion 108b-7 located on an inner side of the upper lens support portion 108a-7. The concave portion 108b-7 of the upper lens 108-7 may have a curvature CV8 recessed inward in the upper lens support portion 108a-7. The upper lens 108-7 may be a concave lens.

The upper lens support portion 108a-7 may include a top surface 108-7S1 exposed to the outside and a bottom surface 108-7S2 bonded to the intermediate lens layer 106-7. The top surface 108-7S1 of the upper lens support portion 108a-7 is flat and thus may easily receive light from the optical fiber array.

Each of the optical glue layer 102, the intermediate lens layer 106-7, and the lens protective layer 107-7 may include a material capable of easily transmitting an optical signal to the grating coupler GC. In some embodiments, the optical glue layer 102, the intermediate lens layer 106-7, and the lens protective layer 107-7 may include an ultraviolet curing optical adhesive.

In some embodiments, the optical glue layer 102, the intermediate lens layer 106-7, and the lens protective layer 107-7 may include epoxy resin, silicone resin, silane resin, or acrylate resin, as well as filler particles or a curing agent added thereto.

Each of the intermediate lens layer 106-7 and the lens protective layer 107-7 may be configured to have a different refractive index from each of the multilayer lenses 104-7 and 108-7 by adjusting the types of the aforementioned materials or the amount of additives such as filler particles or a curing agent during manufacturing.

Polarization or focusing of light incident through the optical block OPB7 configured as described above may be adjusted, thereby further increasing the alignment margin between the optical block OPB7 and the grating coupler GC of the PIC die 10 (of FIG. 1A).

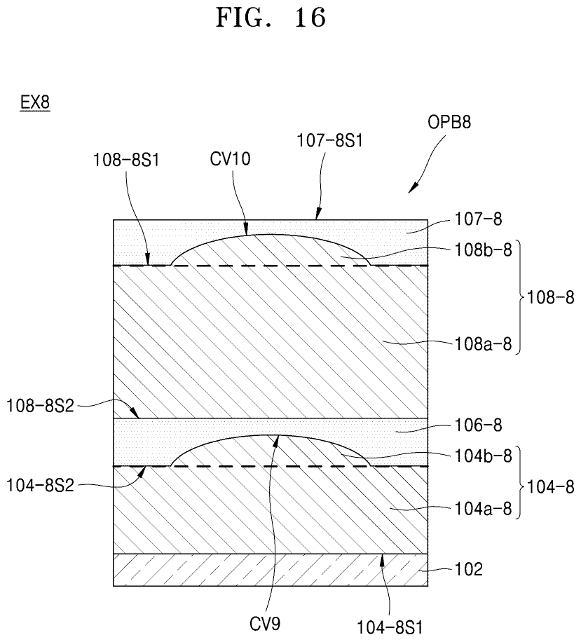

FIG. 16 is a cross-sectional view showing an optical block of a semiconductor package according to an embodiment.

In detail, a semiconductor package EX8 may include an optical block OPB8. The optical block OPB8 may replace the optical block OPB1 of the semiconductor package EX1 of FIG. 1A. In FIG. 16, the same or similar reference numerals as those in FIGS. 1A to 4 denote the same or similar components. For FIG. 16, descriptions provided with reference to FIGS. 1A to 4 are briefly provided or omitted.

The optical block OPB8 may be bonded to the PIC die 10 (of FIG. 1A) by the optical glue layer 102. The optical block OPB8 may include multilayer lenses 104-8 and 108-8, an intermediate lens layer 106-8, and a lens protective layer 107-8. The intermediate lens layer 106-8 may be located between the multilayer lenses 104-8 and 108-8 and bond the multilayer lenses 104-8 and 108-8 together. The lens protective layer 107-8 may be located above the upper lens 108-8 to protect the upper lens 108-8.

In some embodiments, the multilayer lenses 104-8 and 108-8 may include glass or silicone. In some embodiments, each of the intermediate lens layer 106-8 and the lens protective layer 107-8 may include a material having a different refractive index from each of the multilayer lenses 104-8 and 108-8. In some embodiments, the multilayer lenses 104-8 and 108-8 may include materials having different refractive indices from each other.

The multilayer lenses 104-8 and 108-8 may include the lower lens 104-8 and the upper lens 108-8. The multilayer lenses 104-8 and 108-8 may include a combination of convex lenses.

The lower lens 104-8 may include a lower lens support portion 104a-8 and a lower lens core portion 104b-8. The lower lens core portion 104b-8 may have a curvature CV9 protruding outward. The lower lens 104-8 may be a convex lens.

The lower lens support portion 104a-8 may include a bottom surface 104-8S1 bonded to the optical glue layer 102 and a top surface 104-8S2 bonded to the lower lens core portion 104b-8 and the intermediate lens layer 106-8. Because the bottom surface 104-8S1 of the lower lens support portion 104a-8 is flat, the optical block OPB8 may improve bonding accuracy with the optical glue layer 102 and may be easily bonded to the optical glue layer 102.

The upper lens 108-8 may be bonded onto the lower lens support portion 104a-8 and the lower lens core portion 104b-8 by the intermediate lens layer 106-8. The upper lens 108-8 may include an upper lens support portion 108a-8 and an upper lens core portion 108b-8. The upper lens core portion 108b-8 may have a curvature CV10 protruding outward from the upper lens support portion 108a-8. The upper lens 108-8 may be a convex lens.

The upper lens support portion 108a-8 may include a top surface 108-8S1 and a bottom surface 108-8S2 bonded to the intermediate lens layer 106-8. A top surface 107-8S1 of the lens protective layer 107-8 is flat and thus may easily receive light from the optical fiber array.

Each of the optical glue layer 102, the intermediate lens layer 106-8, and the lens protective layer 107-8 may include a material capable of easily transmitting an optical signal to the grating coupler GC. In some embodiments, the optical glue layer 102, the intermediate lens layer 106-8, and the lens protective layer 107-8 may include an ultraviolet curing optical adhesive.

In some embodiments, the optical glue layer 102, the intermediate lens layer 106-8, and the lens protective layer 107-8 may include epoxy resin, silicone resin, silane resin, or acrylate resin, as well as filler particles or a curing agent added thereto.

Each of the intermediate lens layer 106-8 and the lens protective layer 107-8 may be configured to have a different refractive index from each of the multilayer lenses 104-8 and 108-8 by adjusting the types of the aforementioned materials or the amount of additives such as filler particles or a curing agent during manufacturing.

Polarization or focusing of light incident through the optical block OPB8 configured as described above may be adjusted, thereby further increasing the alignment margin between the optical block OPB8 and the grating coupler GC of the PIC die 10 (of FIG. 1A).

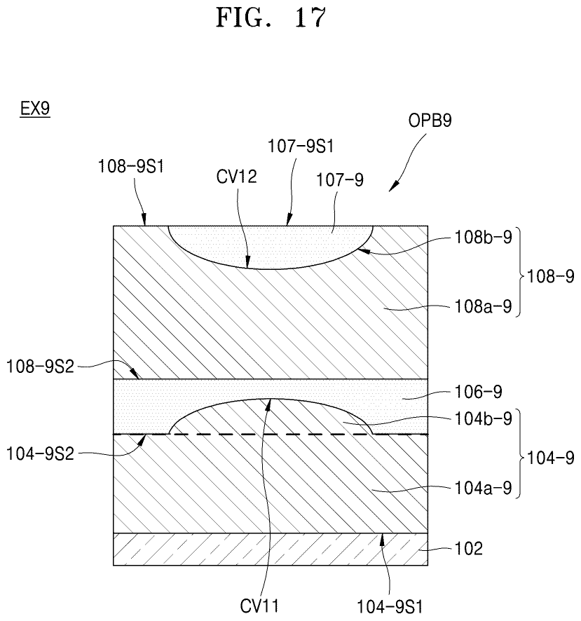

FIG. 17 is a cross-sectional view showing an optical block of a semiconductor package according to an embodiment.

In detail, a semiconductor package EX9 may include an optical block OPB9. The optical block OPB9 may replace the optical block OPB1 of the semiconductor package EX1 of FIG. 1A. In FIG. 17, the same or similar reference numerals as those in FIGS. 1A to 4 denote the same or similar components. For FIG. 17, descriptions provided with reference to FIGS. 1A to 4 are briefly provided or omitted.

The optical block OPB9 may be bonded to the PIC die 10 (of FIG. 1A) by the optical glue layer 102. The optical block OPB9 may include multilayer lenses 104-9 and 108-9, an intermediate lens layer 106-9, and a lens protective layer 107-9. The intermediate lens layer 106-9 may be located between the multilayer lenses 104-9 and 108-9 and bond the multilayer lenses 104-9 and 108-9 together. The lens protective layer 107-9 may be located above the upper lens 108-9 to protect the upper lens 108-9.

In some embodiments, the multilayer lenses 104-9 and 108-9 may include glass or silicone. In some embodiments, each of the intermediate lens layer 106-9 and the lens protective layer 107-9 may include a material having a different refractive index from each of the multilayer lenses 104-9 and 108-9. In some embodiments, the multilayer lenses 104-9 and 108-9 may include materials having different refractive indices from each other.

The multilayer lenses 104-9 and 108-9 may include the lower lens 104-9 and the upper lens 108-9. The multilayer lenses 104-9 and 108-9 may include a combination of a convex lens and a concave lens. The lower lens 104-9 may include a lower lens support portion 104a-9 and a lower lens core portion 104b-9. The lower lens core portion 104b-9 may have a curvature CV11 protruding outward. The lower lens 104-9 may be a convex lens.

The lower lens support portion 104a-9 may include a bottom surface 104-9S1 bonded to the optical glue layer 102 and a top surface 104-9S2 bonded to the lower lens core portion 104b-9 and the intermediate lens layer 106-9. Because the bottom surface 104-9S1 of the lower lens support portion 104a-9 is flat, the optical block OPB9 may improve bonding accuracy with the optical glue layer 102 and may be easily bonded to the optical glue layer 102.

The upper lens 108-9 may be bonded onto the lower lens support portion 104a-9 and the lower lens core portion 104b-9 by the intermediate lens layer 106-9. The upper lens 108-9 may include an upper lens support portion 108a-9 and a concave portion 108b-9 located on an inner side of the upper lens support portion 108a-9. The concave portion 108b-9 of the upper lens 108-9 may have a curvature CV12 recessed inward in the upper lens support portion 108a-9. The upper lens 108-9 may be a concave lens.

The upper lens support portion 108a-9 may include a top surface 108-9S1 and a bottom surface 108-9S2 bonded to the intermediate lens layer 106-9. A top surface 107-9S1 of the lens protective layer 107-9 is flat and thus may easily receive light from the optical fiber array.

Each of the optical glue layer 102, the intermediate lens layer 106-9, and the lens protective layer 107-9 may include a material capable of easily transmitting an optical signal to the grating coupler GC. In some embodiments, the optical glue layer 102, the intermediate lens layer 106-9, and the lens protective layer 107-9 may include an ultraviolet curing optical adhesive.

In some embodiments, the optical glue layer 102, the intermediate lens layer 106-9, and the lens protective layer 107-9 may include epoxy resin, silicone resin, silane resin, or acrylate resin, as well as filler particles or a curing agent added thereto.

Each of the intermediate lens layer 106-9 and the lens protective layer 107-9 may be configured to have a different refractive index from each of the multilayer lenses 104-9 and 108-9 by adjusting the types of the aforementioned materials or the amount of additives such as filler particles or a curing agent during manufacturing.

Polarization or focusing of light incident through the optical block OPB9 configured as described above may be adjusted, thereby further increasing the alignment margin between the optical block OPB9 and the grating coupler GC of the PIC die 10 (of FIG. 1A).

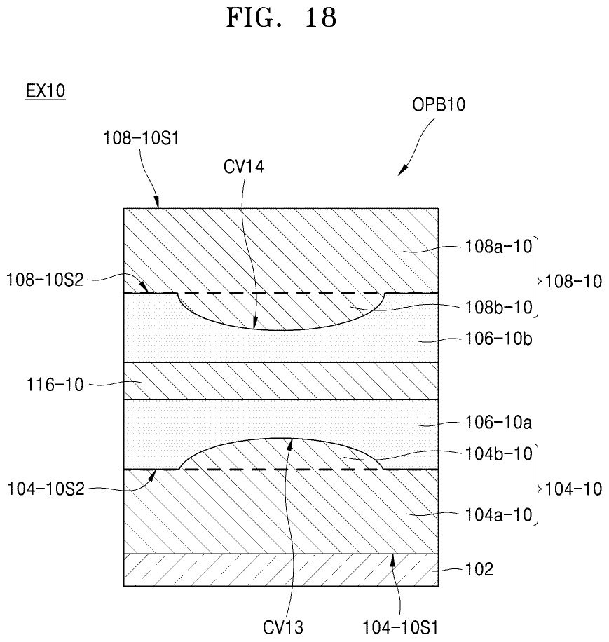

FIG. 18 is a cross-sectional view showing an optical block of a semiconductor package according to an embodiment.

In detail, a semiconductor package EX10 may include an optical block OPB10. The optical block OPB10 may replace the optical block OPB1 of the semiconductor package EX1 of FIG. 1A. In FIG. 18, the same or similar reference numerals as those in FIGS. 1A to 4 denote the same or similar components. For FIG. 18, descriptions provided with reference to FIGS. 1A to 4 are briefly provided or omitted.

The optical block OPB10 may be bonded to the PIC die 10 (of FIG. 1A) by the optical glue layer 102. The optical block OPB10 may include multilayer lenses 104-10, 116-10, and 108-10 and intermediate lens layers 106-10a and 106-10b. The intermediate lens layer 106-10a may be located between the multilayer lenses 104-10 and 116-10 and bond the multilayer lenses 104-10 and 116-10 together, and the intermediate lens layer 106-10b may be located between the multilayer lenses 116-10 and 108-10 and bond the multilayer lenses 116-10 and 108-10 together.

In some embodiments, the multilayer lenses 104-10, 116-10, and 108-10 may include glass or silicone. In some embodiments, each of the intermediate lens layers 106-10a and 106-10b may include a material having a different refractive index from each of the multilayer lenses 104-10, 116-10, and 108-10. In some embodiments, the multilayer lenses 104-10, 116-10, and 108-10 may include materials having different refractive indices from one another.

The multilayer lenses 104-10, 116-10, and 108-10 may include the lower lens 104-10, the intermediate lens 116-10, and the upper lens 108-10. The multilayer lenses 104-10, 116-10, and 108-10 may include a combination of convex lenses and a flat plate-type lens.

The lower lens 104-10 may include a lower lens support portion 104a-10 and a lower lens core portion 104b-10. The lower lens core portion 104b-10 may have a curvature CV13 protruding outward. The lower lens 104-10 may be a convex lens.

The lower lens support portion 104a-10 may include a bottom surface 104-10S1 bonded to the optical glue layer 102 and a top surface 104-10S2 bonded to the lower lens core portion 104b-10 and the intermediate lens layer 106-10a. Because the bottom surface 104-10S1 of the lower lens support portion 104a-10 is flat, the optical block OPB10 may improve bonding accuracy with the optical glue layer 102 and may be easily bonded to the optical glue layer 102.

The intermediate lens layers 106-10a and 106-10b may include the lower intermediate lens layer 106-10a and the upper intermediate lens layer 106-10b. The intermediate lens 116-10 may be bonded to the lower lens 104-10 by the lower intermediate lens layer 106-10a. The intermediate lens 116-10 may be bonded to the upper lens 108-10 by the upper intermediate lens layer 106-10b. The intermediate lens 116-10 may be a flat plate-type lens having a flat top surface and a flat bottom surface.

The upper lens 108-10 may be bonded to the intermediate lens 116-10 by the upper intermediate lens layer 106-10b. The upper lens 108-10 may include an upper lens support portion 108a-10 and an upper lens core portion 108b-10 located outside the upper lens support portion 108a-10.

The upper lens core portion 108b-10 may include a concave portion protruding outward from the upper lens support portion 108a-10. The upper lens core portion 108b-10 may have a curvature CV14 protruding outward. The upper lens 108-10 may be a convex lens.

The upper lens support portion 108a-10 may include a top surface 108-10S1 and a bottom surface 108-10S2 bonded to the upper intermediate lens layer 106-10b. The top surface 108-10S1 of the upper lens support portion 108a-10 is flat and thus may easily receive light from the optical fiber array.

Each of the optical glue layer 102 and the intermediate lens layers 106-10a and 106-10b may include a material capable of easily transmitting an optical signal to the grating coupler GC. In some embodiments, the optical glue layer 102 and the intermediate lens layers 106-10a and 106-10b may include an ultraviolet curing optical adhesive.

In some embodiments, the optical glue layer 102 and the intermediate lens layers 106-10a and 106-10b may include epoxy resin, silicone resin, silane resin, or acrylate resin, as well as filler particles or a curing agent added thereto.

Each of the intermediate lens layers 106-10a and 106-10b may be configured to have a different refractive index from each of the multilayer lenses 104-10, 116-10, and 108-10 by adjusting the types of the aforementioned materials or the amount of additives such as filler particles or a curing agent during manufacturing.

Polarization or focusing of light incident through the optical block OPB10 configured as described above may be adjusted, thereby further increasing the alignment margin between the optical block OPB10 and the grating coupler GC of the PIC die 10 (of FIG. 1A).

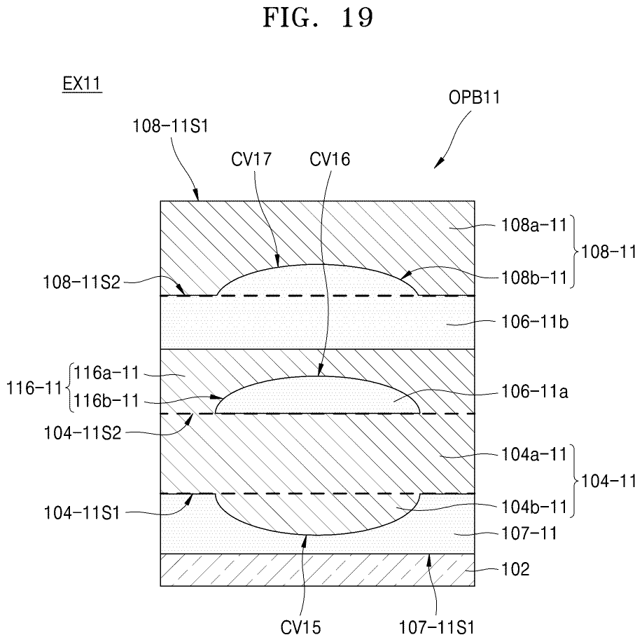

FIG. 19 is a cross-sectional view showing an optical block of a semiconductor package according to an embodiment.

In detail, a semiconductor package EX11 may include an optical block OPB11. The optical block OPB11 may replace the optical block OPB1 of the semiconductor package EX1 of FIG. 1A. In FIG. 19, the same or similar reference numerals as those in FIGS. 1A to 4 denote the same or similar components. For FIG. 19, descriptions provided with reference to FIGS. 1A to 4 are briefly provided or omitted.

The optical block OPB11 may be bonded to the PIC die 10 (of FIG. 1A) by the optical glue layer 102. The optical block OPB11 may include multilayer lenses 104-11, 116-11, and 108-11, intermediate lens layers 106-11a and 106-11b, and a lens protective layer 107-11. The intermediate lens layer 106-11a and 106-11b may be located between the multilayer lenses 104-11 and 108-11 and bond the multilayer lenses 104-11 and 108-11 together. The lens protective layer 107-11 may be located under the lower lens 104-11 to protect the lower lens 104-11.

In some embodiments, the multilayer lenses 104-11, 116-11, and 108-11 may include glass or silicone. In some embodiments, each of the intermediate lens layers 106-11a and 106-11b and the lens protective layer 107-11 may include a material having a different refractive index from each of the multilayer lenses 104-11, 116-11, and 108-11. In some embodiments, the multilayer lenses 104-11, 116-11, and 108-11 may include materials having different refractive indices from one another.

The multilayer lenses 104-11, 116-11, and 108-11 may include the lower lens 104-11, the intermediate lens 116-11, and the upper lens 108-11. The multilayer lenses 104-11, 116-11, and 108-11 may include a combination of a convex lens and concave lenses.

The lower lens 104-11 may include a lower lens support portion 104a-11 and a lower lens core portion 104b-11. The lower lens core portion 104b-11 may have a curvature CV15 protruding outward. The lower lens 104-11 may be a convex lens.

The lower lens support portion 104a-11 may include a bottom surface 104-11S1 bonded to the lens protective layer 107-11 and a top surface 104-11S2 bonded to the intermediate lens 116-11. The lens protective layer 107-11 may include a bottom surface 107-11S1 bonded to the optical glue layer 102. Because the bottom surface 107-11S1 of the lens protective layer 107-11 is flat, the optical block OPB11 may improve bonding accuracy with the optical glue layer 102 and may be easily bonded to the optical glue layer 102.

The intermediate lens layers 106-11a and 106-11b may include the lower intermediate lens layer 106-11a and the upper intermediate lens layer 106-11b. The intermediate lens 116-11 may include an intermediate lens support portion 116a-11 and a concave portion 116b-11 located on an inner side of the intermediate lens support portion 116a-11. The concave portion 116b-11 of the intermediate lens 116-11 may have a curvature CV16 recessed inward in the intermediate lens support portion 116a-11. The intermediate lens 116-11 may be a concave lens.

The upper lens 108-11 may be bonded to the intermediate lens 116-11 by the upper intermediate lens layer 106-11b. The upper lens 108-11 may include an upper lens support portion 108a-11 and a concave portion 108b-11 located on an inner side of the upper lens support portion 108a-11. The concave portion 108b-11 may have a curvature CV17 recessed inward. The upper lens 108-11 may be a concave lens.

The upper lens support portion 108a-11 may include a top surface 108-11S1 and a bottom surface 108-11S2 bonded to the upper intermediate lens layer 106-11b. The top surface 108-11S1 of the upper lens support portion 108a-11 is flat and thus may easily receive light from the optical fiber array.

Each of the optical glue layer 102 and the intermediate lens layers 106-11a and 106-11b may include a material capable of easily transmitting an optical signal to the grating coupler GC. In some embodiments, the optical glue layer 102 and the intermediate lens layers 106-11a and 106-11b may include an ultraviolet curing optical adhesive.

In some embodiments, the optical glue layer 102 and the intermediate lens layers 106-11a and 106-11b may include epoxy resin, silicone resin, silane resin, or acrylate resin, as well as filler particles or a curing agent added thereto.

Each of the intermediate lens layers 106-11a and 106-11b may be configured to have a different refractive index from each of the multilayer lenses 104-11, 116-11, and 108-11 by adjusting the types of the aforementioned materials or the amount of additives such as filler particles or a curing agent during manufacturing.

Polarization or focusing of light incident through the optical block OPB11 configured as described above may be adjusted, thereby further increasing the alignment margin between the optical block OPB11 and the grating coupler GC of the PIC die 10 (of FIG. 1A).

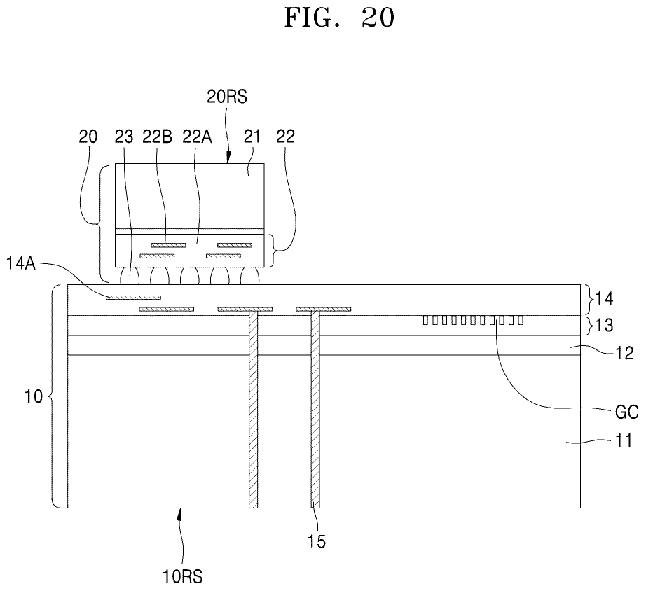

FIGS. 20 to 24 are cross-sectional views for describing a method of manufacturing a semiconductor package, according to an embodiment.

In detail, FIGS. 20 to 24 are provided to describe a method of manufacturing the semiconductor package EX1 of FIGS. 1A to 4. In FIGS. 20 to 24, the same or similar reference numerals as those in FIGS. 1A to 4 denote the same or similar components. For FIGS. 20 to 24, descriptions provided with reference to FIGS. 1A to 4 are briefly provided or omitted.

The method of manufacturing the semiconductor package EX1 may include, after preparing the EIC die 20 as shown in FIG. 20, mounting the EIC die 20 on the PIC die 10.

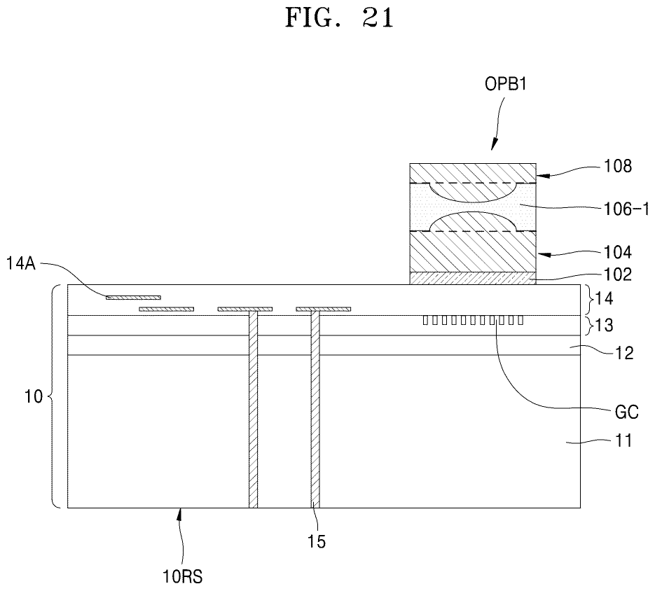

Alternatively, the method of manufacturing the semiconductor package EX1 may include, after preparing the optical block OPB1 as shown in FIG. 21, mounting the optical block OPB1 on the PIC die 10.

Referring to FIG. 20, the method includes, after preparing the EIC die 20, first mounting the EIC die 20 on the PIC die 10. The PIC die 10 may include the semiconductor substrate 11, the dielectric layer 12, and the light-guiding layer 13. The semiconductor substrate 11 may include a conductive layer, a transistor, a diode, a resistor, a capacitor, or a semiconductor element. The light-guiding layer 13 may be formed on the dielectric layer 12.

The light-guiding layer 13 may include the grating coupler GC and the optical waveguide WG. The optical waveguide WG arranged within the light-guiding layer 13 may be optically connected to the grating coupler GC.

The grating coupler GC may operate as an optical input/output apparatus of the PIC die 10. The PIC die 10 may include various apparatuses or circuits capable of processing and transmitting optical signals or electrical signals. The PIC die 10 may also be referred to as an optoelectronic integrated circuit die.

In some embodiments, the PIC die 10 may further include the wiring structure 14 and the through via 15. The wiring structure 14 may be electrically connected to the through via 15. The wiring structure 14 may be electrically connected to the conductive layer formed within the semiconductor substrate 11 or to other semiconductor devices.

The EIC die 20 may be electrically connected to the PIC die 10. The EIC die 20 may include the semiconductor substrate 21 and the wiring structure 22 arranged on the semiconductor substrate 21. The semiconductor substrate 21 may include a conductive layer, a transistor, a diode, a resistor, a capacitor, or a semiconductor element. The wiring structure 22 may include the dielectric layer 22A and the wiring layer 22B formed within the dielectric layer 22A.

The EIC die 20 may be electrically connected to the PIC die 10 through the plurality of electrical terminals 23. The electrical terminals 23 may be micro bumps, BGA connectors, solder balls, or metal pillars.

Referring to FIG. 21, the method includes, after preparing the optical block OPB1, first mounting the optical block OPB1 on the PIC die 10. Because the PIC die 10 has been described above, the descriptions thereof will be omitted hereinafter.

The optical block OPB1 may be mounted on the light-guiding layer 13 of the PIC die 10 in alignment with the grating coupler GC. The optical block OPB1 may be bonded to the PIC die 10 by the optical glue layer 102. The optical block OPB1 may include the multilayer lenses 104 and 108 and the intermediate lens layer 106-1 which is located between the multilayer lenses 104 and 108 and bonds the multilayer lenses 104 and 108 together.

In some embodiments, the multilayer lenses 104 and 108 may include glass or silicone. In some embodiments, the intermediate lens layer 106-1 may include a material having the same refractive index as each of the multilayer lenses 104 and 108. In some embodiments, the multilayer lenses 104 and 108 may include materials having different refractive indices from each other.

The multilayer lenses 104 and 108 may include the lower lens 104 and the upper lens 108. The lower lens 104 may be bonded to the optical glue layer 102. Because a bottom surface of the lower lens 104 is flat, the optical block OPB1 may be easily bonded to the optical glue layer 102. A top surface of the upper lens support portion 108a is flat and thus may easily receive light from the optical fiber array.

Each of the optical glue layer 102 and the intermediate lens layer 106-1 may include a material capable of easily transmitting an optical signal to the grating coupler GC. In some embodiments, the optical glue layer 102 and the intermediate lens layer 106-1 may include an ultraviolet curing optical adhesive.

In some embodiments, the optical glue layer 102 and the intermediate lens layer 106-1 may include epoxy resin, silicone resin, silane resin, or acrylate resin, as well as filler particles or a curing agent added thereto.

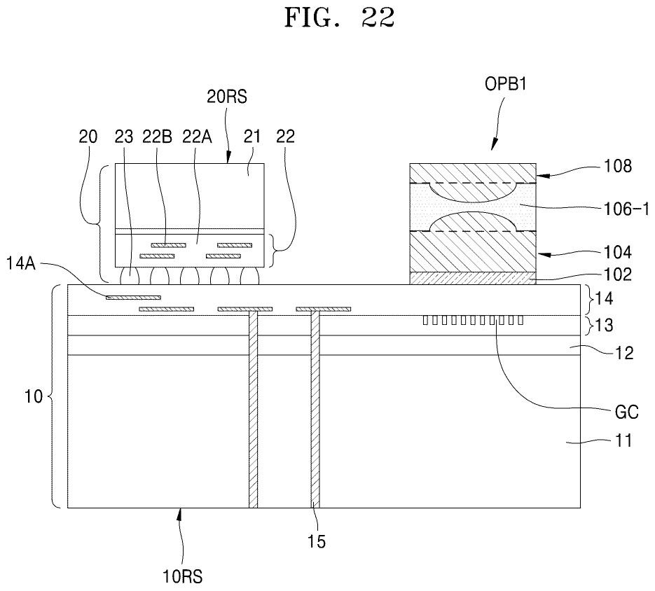

Referring to FIG. 22, after the EIC die 20 is first mounted on the PIC die 10 as shown in FIG. 20, the optical block OPB1 may be mounted on the PIC die 10 as shown in FIG. 21.

Alternatively, after the optical block OPB1 is first mounted on the PIC die 10 as shown in FIG. 21, the EIC die 20 may be mounted on the PIC die 10 as shown in FIG. 20.

In this case, the EIC die 20 and the optical block OPB1 may be mounted on the PIC die 10 as shown in FIG. 22. The optical block OPB1 may be spaced apart from the EIC die 20.

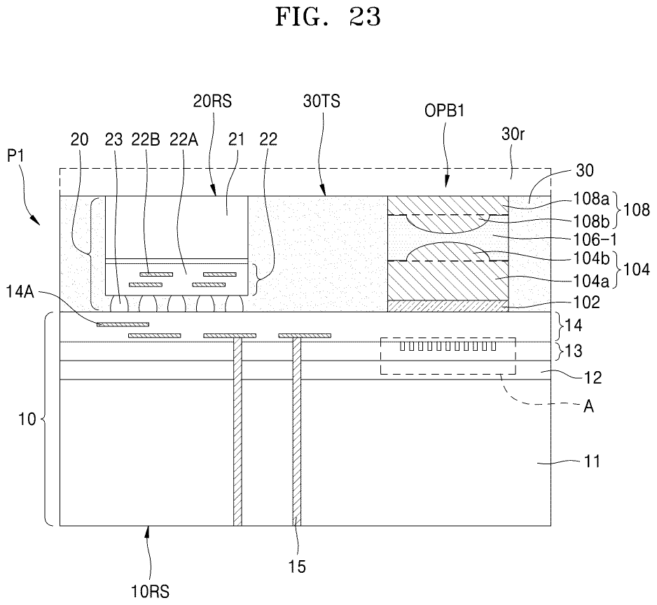

Referring to FIG. 23, the molding layer 30 is formed by molding the EIC die 20 and the optical block OPB1, which are located on the PIC die 10. A molding material layer 30r is formed that sufficiently covers the EIC die 20 and the optical block OPB1, which are located on the PIC die 10.

The molding material layer 30r may include a base material and filler particles distributed within the base material. The base material may include epoxy resin, phenol resin, or silicone-containing resin. The filler particles may include silica, alumina, zinc oxide, or titanium oxide.

The molding layer 30 is formed by planarizing (or etching) the molding material layer 30r by using the bottom surface 20RS of the EIC die 20 and a top surface of the optical block OPB1 as an etch stop level through a planarization process, for example, a chemical mechanical polishing process. During the planarization process for the molding material layer 30r, the optical block OPB1 may be easily planarized because the upper lens 108 does not protrude.

The molding layer 30 may mold side surfaces and a bottom surface of the EIC die 20. The molding layer 30 may mold side surfaces of the optical block OPB1. The top surface 108S1 of the optical block OPB1 may not protrude beyond the top surface 30TS of the molding layer 30 and may be coplanar with the top surface 30TS of the molding layer 30.

The bottom surface 20RS of the EIC die 20, the top surface 30TS of the molding layer 30, and the top surface 108S1 of the optical block OPB1 may be coplanar with each other. The package structure P1 including the EIC die 20, the optical block OPB1, and the molding layer 30 may be formed on the PIC die 10.

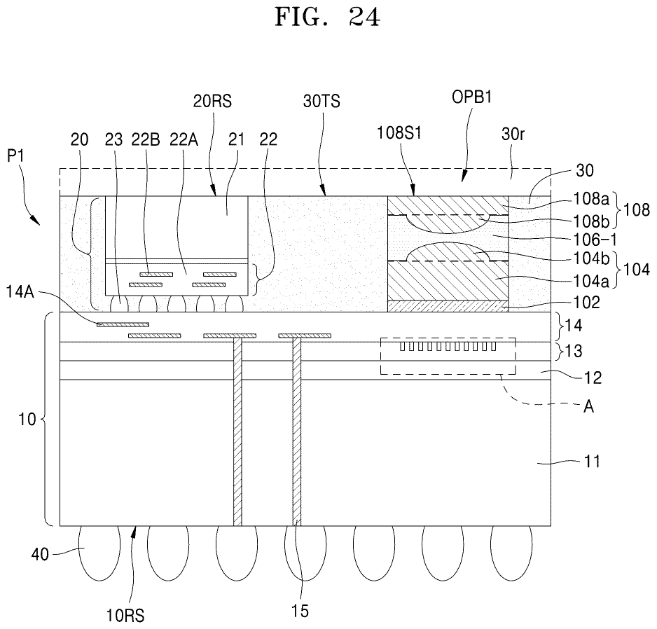

Referring to FIG. 24, the electrical terminals 40 are formed on the bottom surface 10RS of the PIC die 10. Subsequently, the semiconductor package may be completed by mounting, on the package substrate S shown in FIG. 1A, the package structure P1 having the electrical terminals 40 formed thereon.

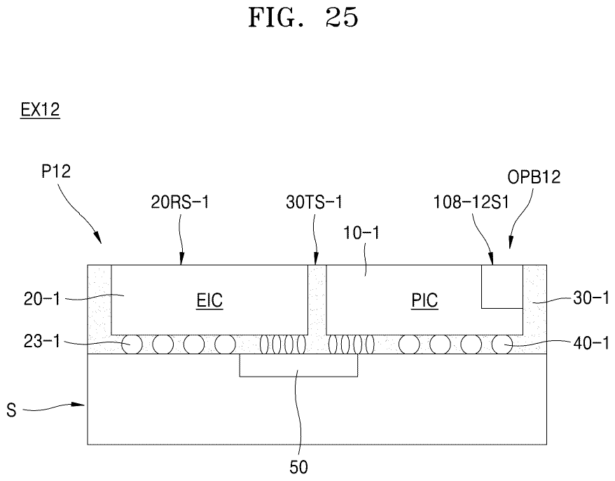

FIG. 25 is a cross-sectional view for describing a semiconductor package according to an embodiment.

In detail, a semiconductor package EX12 may be substantially the same as that shown in FIGS. 1A to 4, except that an EIC die 20-1 and a PIC die 10-1 of a package structure P12 are horizontally spaced apart from each other.

In FIG. 25, the same or similar reference numerals as those in FIGS. 1A to 4 denote the same or similar components. For FIG. 25, descriptions provided with reference to FIGS. 1A to 4 are briefly provided or omitted.

The semiconductor package EX12 may include the package substrate S and the package structure P12 mounted on the package substrate S. The package structure P12 may include the PIC die 10-1, the EIC die 20-1, an optical block OPB12, and a molding layer 30-1.

The PIC die 10-1 and the EIC die 20-1 may be mounted on the package substrate S. The PIC die 10-1 may include electrical terminals 40-1. The EIC die 20-1 may include electrical terminals 23-1. The electrical terminals 40-1 of the PIC die 10-1 and the electrical terminals 23-1 of the EIC die 20-1 may be electrically connected to each other by a bridge circuit 50 formed on the package substrate S.

The optical block OPB12 may be formed on the PIC die 10-1. The molding layer 30-1 may mold the EIC die 20-1, the PIC die 10-1, and the optical block OPB12, on the package substrate S. The molding layer 30-1 may mold side surfaces of the EIC die 20-1, side surfaces of the PIC die 10-1, and side surfaces of the optical block OPB12, on the package substrate S.

A top surface 108-12S1 of the optical block OPB12 may not protrude beyond a top surface 30TS-1 of the molding layer 30 and may be coplanar with the top surface 30TS-1 of the molding layer 30-1. A bottom surface 20RS-1 of the EIC die 20-1, the top surface 30TS-1 of the molding layer 30-1, and the top surface 108-12S1 of the optical block OPB12 may be coplanar with each other.

The optical block OPB12 may be bonded to the PIC die 10-1. The optical block OPB12 may include the multilayer lenses 104 and 108 (of FIG. 1A) and the intermediate lens layer 106-1 (of FIG. 1A) which is located between the multilayer lenses 104 and 108 (of FIG. 1A) and bonds the multilayer lenses 104 and 108 (of FIG. 1A) together, as described above.

Accordingly, the semiconductor package EX12 may increase the alignment margin between the optical block OPB12 and the grating coupler GC (of FIG. 1B) of the PIC die 10-1 and may reduce insertion loss of light incident through the optical block OPB12.

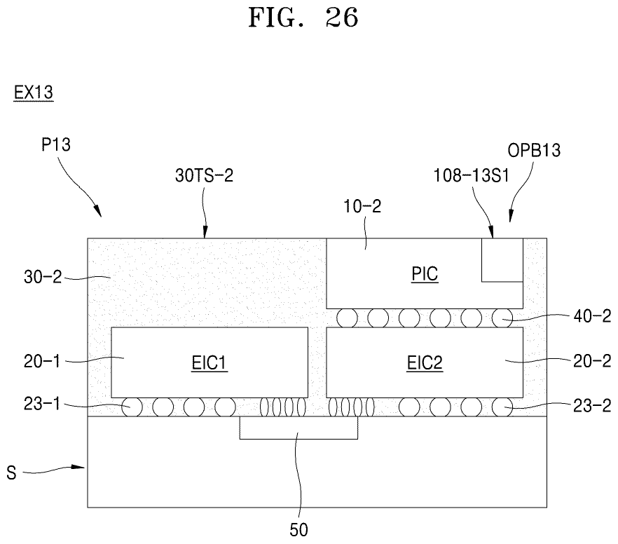

FIG. 26 is a cross-sectional view for describing a semiconductor package according to an embodiment.

In detail, a semiconductor package EX13 may be substantially the same as those shown in FIGS. 1A to 4 and 25, except that a PIC die 10-2 of a package structure P13 is stacked on a second EIC die 20-2.

In FIG. 26, the same or similar reference numerals as those in FIGS. 1A to 4 and 25 denote the same or similar components. For FIG. 26, descriptions provided with reference to FIGS. 1A to 4 and 25 are briefly provided or omitted.

The semiconductor package EX13 may include the package substrate S and the package structure P13 mounted on the package substrate S. The package structure P13 may include the PIC die 10-2, the first EIC die 20-1, the second EIC die 20-2, an optical block OPB13, and a molding layer 30-2.

The first EIC die 20-1 and the second EIC die 20-2 may be mounted on the package substrate S. The first EIC die 20-1 may include the electrical terminals 23-1. The second EIC die 20-2 may include electrical terminals 23-2. The electrical terminals 23-1 of the first EIC die 20-1 and the electrical terminals 23-2 of the second EIC die 20-2 may be electrically connected to each other by the bridge circuit 50 formed on the package substrate S.

The PIC die 10-2 may be mounted on the second EIC die 20-2. The PIC die 10-2 may include electrical terminals 40-2. The electrical terminals 40-2 of the PIC die 10-2 may be electrically connected to the second EIC die 20-2.

The optical block OPB13 may be formed on the PIC die 10-2. The molding layer 30-2 may mold the first EIC die 20-1, the second EIC die 20-2, the PIC die 10-2, and the optical block OPB13, on the package substrate S. The molding layer 30-2 may mold side surfaces and a top surface of the first EIC die 20-1, side surfaces and a top surface of the second EIC die 20-2, side surfaces of the PIC die 10-2, and side surfaces of the optical block OPB13, on the package substrate S.

A top surface 108-13S1 of the optical block OPB13 may not protrude beyond a top surface 30TS-2 of the molding layer 30-2 and may be coplanar with the top surface 30TS-2 of the molding layer 30-2. The optical block OPB13 may be bonded to the PIC die 10-2.

The optical block OPB13 may include the multilayer lenses 104 and 108 (of FIG. 1A) and the intermediate lens layer 106-1 (of FIG. 1A) which is located between the multilayer lenses 104 and 108 (of FIG. 1A) and bonds the multilayer lenses 104 and 108 (of FIG. 1A) together, as described above.

Accordingly, the semiconductor package EX13 may increase the alignment margin between the optical block OPB13 and the grating coupler GC (of FIG. 1B) of the PIC die 10-2 and may reduce insertion loss of light incident through the optical block OPB13.

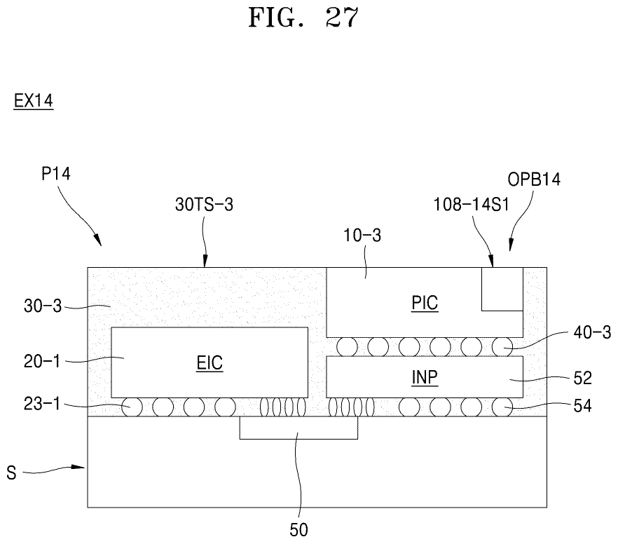

FIG. 27 is a cross-sectional view for describing a semiconductor package according to an embodiment.

In detail, a semiconductor package EX14 may be substantially the same as those shown in FIGS. 1A to 4 and 25, except that a PIC die 10-3 of a package structure P14 is stacked on an interposer die (INP) 52.

In FIG. 27, the same or similar reference numerals as those in FIGS. 1A to 4 and 25 denote the same or similar components. For FIG. 27, descriptions provided with reference to FIGS. 1A to 4 and 25 are briefly provided or omitted.

The semiconductor package EX14 may include the package substrate S and the package structure P14 mounted on the package substrate S. The package structure P14 may include the PIC die 10-3, the first EIC die 20-1, the interposer die 52, an optical block OPB14, and a molding layer 30-3.

The EIC die 20-1 and the interposer die 52 may be mounted on the package substrate S. The EIC die 20-1 may include the electrical terminals 23-1. The interposer die 52 may include electrical terminals 54. The electrical terminals 23-1 of the EIC die 20-1 and the electrical terminals 54 of the interposer die 52 may be electrically connected to each other by the bridge circuit 50 formed on the package substrate S.

The PIC die 10-3 may be mounted on the interposer die 52. The PIC die 10-3 may include electrical terminals 40-3. The electrical terminals 40-3 of the PIC die 10-3 may be electrically connected to the interposer die 52.

The optical block OPB14 may be formed on the PIC die 10-3. The molding layer 30-3 may mold the EIC die 20-1, the interposer die 52, the PIC die 10-3, and the optical block OPB14, on the package substrate S. The molding layer 30-3 may mold side surfaces and a top surface of the EIC die 20-1, side surfaces and a top surface of the interposer die 52, side surfaces of the PIC die 10-3, and side surfaces of the optical block OPB14, on the package substrate S.

A top surface 108-14S1 of the optical block OPB14 may not protrude beyond a top surface 30TS-3 of the molding layer 30-3 and may be coplanar with the top surface 30TS-3 of the molding layer 30-3. The optical block OPB14 may be bonded to the PIC die 10-3. The optical block OPB14 may include the multilayer lenses 104 and 108 (of FIG. 1A) and the intermediate lens layer 106-1 (of FIG. 1A) which is located between the multilayer lenses 104 and 108 (of FIG. 1A) and bonds the multilayer lenses 104 and 108 (of FIG. 1A) together, as described above.

Accordingly, the semiconductor package EX14 may increase the alignment margin between the optical block OPB14 and the grating coupler GC (of FIG. 1B) of the PIC die 10-3 and may reduce insertion loss of light incident through the optical block OPB14.

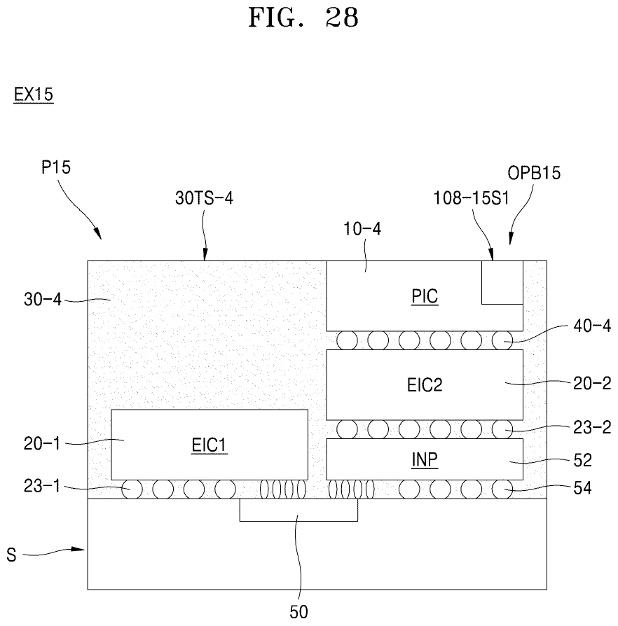

FIG. 28 is a cross-sectional view for describing a semiconductor package according to an embodiment.

In detail, a semiconductor package EX15 may be substantially the same as those shown in FIGS. 1A to 4 and 25, except that a PIC die 10-4 of a package structure P15 is stacked on the second EIC die 20-2.

In FIG. 28, the same or similar reference numerals as those in FIGS. 1A to 4 and 25 denote the same or similar components. For FIG. 28, descriptions provided with reference to FIGS. 1A to 4 and 25 are briefly provided or omitted.

The semiconductor package EX15 may include the package substrate S and the package structure P15 mounted on the package substrate S. The package structure P15 may include the PIC die 10-4, the first EIC die 20-1, the interposer die 52, the second EIC die 20-2, an optical block OPB15, and a molding layer 30-4.

The first EIC die 20-1 and the interposer die 52 may be mounted on the package substrate S. The first EIC die 20-1 may include the electrical terminals 23-1. The interposer die 52 may include the electrical terminals 54. The electrical terminals 23-1 of the first EIC die 20-1 and the electrical terminals 54 of the interposer die 52 may be electrically connected to each other by the bridge circuit 50 formed on the package substrate S.

The second EIC die 20-2 may be mounted on the interposer die 52. The second EIC die 20-2 may include the electrical terminals 23-2. The electrical terminals 23-2 of the second EIC die 20-2 may be electrically connected to the interposer die 52.

The PIC die 10-4 may be mounted on the second EIC die 20-2. The PIC die 10-4 may include electrical terminals 40-4. The electrical terminals 40-4 of the PIC die 10-4 may be electrically connected to the second EIC die 20-2.

The optical block OPB15 may be formed on the PIC die 10-4. The molding layer 30-4 may mold the first EIC die 20-1, the interposer die 52, the second EIC die 20-2, the PIC die 10-4, and the optical block OPB15, on the package substrate S. The molding layer 30-4 may mold side surfaces and a top surface of the first EIC die 20-1, side surfaces and a top surface of the interposer die 52, side surfaces and a top surface of the second EIC die 20-2, side surfaces of the PIC die 10-4, and side surfaces of the optical block OPB15, on the package substrate S.

A top surface 108-15S1 of the optical block OPB15 may not protrude beyond a top surface 30TS-4 of the molding layer 30-4 and may be coplanar with the top surface 30TS-4 of the molding layer 30-4. The optical block OPB15 may be bonded to the PIC die 10-4.

The optical block OPB15 may include the multilayer lenses 104 and 108 (of FIG. 1A) and the intermediate lens layer 106-1 (of FIG. 1A) which is located between the multilayer lenses 104 and 108 (of FIG. 1A) and bonds the multilayer lenses 104 and 108 (of FIG. 1A) together, as described above.

Accordingly, the semiconductor package EX15 may increase the alignment margin between the optical block OPB15 and the grating coupler GC (of FIG. 1B) of the PIC die 10-4 and may reduce insertion loss of light incident through the optical block OPB15.

While the inventive concept has been particularly shown and described with reference to embodiments thereof, it will be understood that various changes in form and details may be made therein without departing from the spirit and scope of the following claims.

What is claimed is:

1. A semiconductor package comprising:
an electrical integrated circuit die;
a photonic integrated circuit die having a light-guiding layer comprising a grating coupler;
an optical block mounted on the photonic integrated circuit die and aligned with the grating coupler; and
a molding layer that molds the electrical integrated circuit die and the optical block,
wherein the optical block comprises multilayer lenses and an intermediate lens layer located between the multilayer lenses, and
a top surface of the optical block does not protrude beyond a top surface of the molding layer and is coplanar with the top surface of the molding layer.

2. The semiconductor package of claim 1, wherein the electrical integrated circuit die is mounted on the photonic integrated circuit die, the optical block is mounted so as to be spaced apart from the electrical integrated circuit die, and the molding layer is located on the photonic integrated circuit die and on side surfaces of the electrical integrated circuit die and side surfaces of the optical block.

3. The semiconductor package of claim 1, wherein an optical adhesive is located between the optical block and the photonic integrated circuit die, and
the optical block is bonded to the photonic integrated circuit die using the optical adhesive.

4. The semiconductor package of claim 1, wherein the multilayer lenses comprise at least one selected from a group consisting of a concave lens, a convex lens, a flat plate-type lens, and a combination thereof.

5. The semiconductor package of claim 1, wherein the intermediate lens layer has a different refractive index from each of the multilayer lenses.

6. The semiconductor package of claim 1, wherein the multilayer lenses comprise:
a lower lens bonded to the photonic integrated circuit die; and
an upper lens bonded to the lower lens by the intermediate lens layer.

7. The semiconductor package of claim 6, wherein the lower lens comprises:
a lower lens support portion bonded to the photonic integrated circuit die; and
a lower lens core portion located on the lower lens support portion, and
the upper lens comprises an upper lens core portion and an upper lens support portion located on the upper lens core portion, the upper lens core portion being bonded to the lower lens core portion by the intermediate lens layer and positioned to face the lower lens core portion.

8. The semiconductor package of claim 1, wherein the multilayer lenses comprise a lower lens bonded to the photonic integrated circuit die, an intermediate lens located on the lower lens, and an upper lens located on the intermediate lens, and
the intermediate lens layer comprises:
a lower intermediate lens layer located between the lower lens and the intermediate lens and bonding the lower lens and the intermediate lens together; and
an upper intermediate lens layer located between the intermediate lens and the upper lens and bonding the intermediate lens and the upper lens together.

9. The semiconductor package of claim 8, wherein the lower intermediate lens layer and the upper intermediate lens layer have different refractive indices from each other.

10. A semiconductor package comprising:
an electrical integrated circuit die;
a photonic integrated circuit die having a light-guiding layer comprising a grating coupler;
an optical block mounted on the photonic integrated circuit die and aligned with the grating coupler; and
a molding layer that molds the electrical integrated circuit die and the optical block,
wherein the optical block comprises multilayer lenses, an intermediate lens layer located between the multilayer lenses, and lens bridges located on opposite sides of the intermediate lens layer and in contact with the molding layer, and
a top surface of the optical block does not protrude beyond a top surface of the molding layer and is coplanar with the top surface of the molding layer.

11. The semiconductor package of claim 10, wherein an optical adhesive is located between the optical block and the photonic integrated circuit die, and
the optical block is bonded to the photonic integrated circuit die using the optical adhesive.

12. The semiconductor package of claim 10, wherein the intermediate lens layer and the lens bridges are configured to have different refractive indices from each other.

13. The semiconductor package of claim 10, wherein the intermediate lens layer and the lens bridges are configured to be in contact with and bonded to the multilayer lenses.

14. The semiconductor package of claim 10, wherein the intermediate lens layer is formed as an air layer, and
the lens bridges are configured to be in contact with and bonded to the multilayer lenses.

15. The semiconductor package of claim 10, wherein the multilayer lenses comprise:
a lower lens bonded to the photonic integrated circuit die; and
an upper lens spaced apart from the lower lens by the intermediate lens layer and the lens bridges, and
the multilayer lenses comprise a concave lens, a convex lens, a flat plate-type lens, or a combination thereof.

16. The semiconductor package of claim 15, wherein the lower lens comprises:
a lower lens support portion bonded to the photonic integrated circuit die; and
a lower lens core portion located on the lower lens support portion, and
the upper lens comprises an upper lens core portion and an upper lens support portion located on the upper lens core portion and the lens bridges, the upper lens core portion being spaced apart from the lower lens core portion by the intermediate lens layer and positioned to face the lower lens core portion.

17. The semiconductor package of claim 16, wherein the lens bridges comprise a lower lens bridge formed on the lower lens support portion and an upper lens bridge formed on the upper lens support portion, and
the lower lens bridge and the upper lens bridges are bonded together.

18. The semiconductor package of claim 10, wherein the lens bridges comprise a light absorber or light reflector configured to suppress stray light or adjust polarization of light transmitted through the optical block.

19. A semiconductor package comprising:
a package substrate;
an electrical integrated circuit die mounted on the package substrate;
a photonic integrated circuit die spaced apart from the electrical integrated circuit die and mounted on the package substrate, the photonic integrated circuit die having a light-guiding layer comprising a grating coupler;
an optical block mounted on the photonic integrated circuit die and aligned with the grating coupler; and
a molding layer that molds the electrical integrated circuit die and the optical block,
wherein the optical block comprises multilayer lenses and an intermediate lens layer located between the multilayer lenses, and
a top surface of the optical block does not protrude beyond a top surface of the molding layer and is coplanar with the top surface of the molding layer.

20. The semiconductor package of claim 19, wherein the multilayer lenses comprise:
a lower lens bonded to the photonic integrated circuit die; and
an upper lens bonded to the lower lens by the intermediate lens layer.
